(19) United States
(12) Patent Application Publication
(10) Pub. No.: US 2009/0273004 A1
(43) Pub. Date: Nov. 5, 2009

(54) CHIP PACKAGE STRUCTURE AND METHOD OF MAKING THE SAME

(76) Inventors: Hung-Yi Lin, Tao-Yuan Hsien (TW); Kuan-Jui Huang, Kao-Hsiung Hsien (TW); Yen-Ting Kung, Taoyuan County (TW); She-Fen Tien, Hsinchu County (TW)

Correspondence Address: NORTH AMERICA INTELLECTUAL PROPERTY CORPORATION, P.O. BOX 506, MERRIFIELD, VA, 22116, US

(21) Appl. No.: 12/485,059

(22) Filed: Jun. 16, 2009

Related U.S. Application Data
(63) Continuation-in-part of application No. 11/611,892, filed on Dec. 18, 2006, now abandoned.
Application No. 11/611,892 is a continuation-in-part of application No. 11/612,486, filed on Dec. 19, 2006.
Application No. 11/612,486 is a continuation-in-part of application No. 11/612,490, filed on Dec. 19, 2006, now abandoned.
Application No. 11/612,490 is a continuation-in-part of application No. 11/612,491, filed on Dec. 19, 2006.
Application No. 11/612,491 is a continuation-in-part of application No. 12/481,578, filed on Jun. 10, 2009.
Application No. 12/481,578 is a continuation-in-part of application No. 11/611,892, filed on Dec. 18, 2006, now abandoned.
Application No. 11/611,892 is a continuation-in-part of application No. 11/612,486, filed on Dec. 19, 2006.
Application No. 11/612,486 is a continuation-in-part of application No. 11/612,490, filed on Dec. 19, 2006, now abandoned.
Application No. 11/612,490 is a continuation-in-part of application No. 11/612,491, filed on Dec. 19, 2006.

(30) Foreign Application Priority Data
Jul. 24, 2006 (TW) 095126950
Sep. 3, 2008 (TW) 097133720
Sep. 17, 2008 (TW) 097135619

(51) Int. Cl. H01L 33/00; H01L 21/50

(52) U.S. Cl. 257/99; 438/26; 257/E33.056; 257/E21.499

(57) ABSTRACT

A chip package structure and method thereof uses a semiconductor substrate as a package substrate, which improve heat dissipation. Also, the chip package structure is incorporated with a planarization structure, which renders the chip and the package substrate a substantially planar surface, thereby making formation of a planar patterned conductive layer possible. Accordingly, electrical connections in series or in parallel between chips can be easily implemented by virtue of the planar patterned conductive layer.

### CROSS REFERENCE TO RELATED APPLICATIONS

This application is a continuation-in-part of applicant's earlier applications, Ser. No. 11/611,892, filed Dec. 18, 2006, Ser. No. 11/612,486, filed Dec. 19, 2006, Ser. No. 11/612,490, filed Dec. 19, 2006, Ser. No. 11/612,491, filed Dec. 19, 2006, and Ser. No. 12/481,578, filed Jun. 10, 2009, which is a continuation-in-part of application Ser. No. 11/611,892, filed Dec. 18, 2006, Ser. No. 11/612,486, filed Dec. 19, 2006, Ser. No. 11/612,490, filed Dec. 19, 2006, and Ser. No. 11/612,491, filed Dec. 19, 2006, the entireties of which are incorporated by reference.

### BACKGROUND OF THE INVENTION

1. Field of the Invention

The present invention is related to a chip package and the method of making the same, and more particularly, to a chip package utilizing a semiconductor substrate as a package substrate and having good heat conductivity while able to fulfill electrical connection of a plurality of chips in series or in parallel easily and a wafer level packaging method of chips.

2. Description of the Prior Art

There are mainly two kinds of conventional Surface Mount Device (SMD) light emitting diode (LED) packaging methods: one of which utilizes a leadframe made of metal materials as a package substrate and the LED chip is mounted on the leadframe; the other method utilizes a printed circuit board (PCB) as a package substrate and the LED chip is mounted on the PCB.

FIG. 1 is a schematic view of a conventional LED chip package utilizing leadframe as a package substrate. As shown in FIG. 1, the conventional LED chip package 1 includes a base 2 formed by injection molding technique, and a leadframe 3 immobilized on the base 2 to form a package substrate 4. The LED chip 5 is mounted on the leadframe 3, and encapsulated on the package substrate 4 with package resin 6. One of the electrodes of LED chip 5 is directly electrically connected to the leadframe 3 located on one side of the package substrate 4, while another electrode is electrically connected to the leadframe 3 on the other side of the package substrate 4 via bonding wire 7 by wire bonding technique.

FIG. 2 is a schematic view of another conventional LED chip package utilizing PCB as a package substrate. As shown in FIG. 2, the conventional LED chip package 10 utilizes PCB 11, made of plastic, as a base, and wires 12 made of copper are laid on the PCB 11. The LED chip 13 is mounted on the PCB 11 and encapsulated with package resin 14, wherein one of the electrodes of the LED chip 13 is directly electrically connected to the wire 12 on one side of the PCB 11, and the other electrode is electrically connected to the wire 12 on the other side of the PCB 11 via the bonding wire 15 by wire bonding technique.

However both of the above mentioned conventional LED chip packages share common shortcomings listed as follows. First, the heat dissipation efficiency of conventional LED chip package is low. Whether the LED chip package is a leadframe type or a PCB type, the package substrate and the package resin are poor heat dissipation materials such as plastic or resin, and heat produced while light is emitted by the LED chips may not be quickly and efficiently dissipated. The accumulated heat would lead to increased temperature of the LED chip and therefore influence the illumination efficiency and life span of the LED chip. In addition, the conventional LED chip package utilizes bonding wire formed by the wire bonding technique to implement external electrical connection of the LED chip. However, the bonding wire itself must have a certain arch that has a height higher than the LED chip; hence the fabrication of the lens to be formed would be difficult. In addition, for any other chips such as integrated circuit (IC) chips or microelectromechanical systems (MEMS) chips, the package substrate used also has the problem of insufficient heat dissipation capability and demanded to be improved.

### SUMMARY OF THE INVENTION

It is therefore one of the objectives of the present invention to provide a chip package and a fabrication method thereof to increase heat dissipation efficiency, and to improve the facility of realizing the serial/parallel electrical connection of LEDs.

To achieve the above-mentioned objective, a method of fabricating a chip package is provided. The method of fabricating a chip package includes:
providing a package substrate, and forming a plurality of concave chip mounting areas on an upper surface of the package substrate;
providing a plurality of chips, each of the chips comprising:
   an element substrate;
   an element disposed on the element substrate; and
   at least a first connecting pad and at least a second connecting pad disposed on an upper surface of the element;
mounting a lower surface of the element substrate of each of the chips within each of the chip mounting areas;
forming a planarization structure on the package substrate and the chips, and further forming a plurality of contact holes on the planarization structure, wherein a portion of the first connecting pad and a portion of the second connecting pad of each of the chips are exposed by the contact holes; and
forming an upper patterned conductive layer on the planarization structure, and the upper patterned conductive layer is filled into the contact holes, and the upper patterned conductive layer is electrically connected to the first connecting pad and the second connecting pad of each of the chips.

To achieve the above-mentioned objective, a chip package is further provided. The chip package includes:
a package substrate comprising at least a concave chip mounting area disposed on an upper surface of the package substrate;
at least a chip disposed within the chip mounting area, wherein the chip comprises:
   an element substrate mounted on the package substrate;
   an element disposed on the element substrate; and
   at least a first connecting pad and at least a second connecting pad disposed on an upper surface of the element;
a planarization structure, having a planar surface, disposed on the package substrate and the chip, the planarization structure comprising a plurality of contact holes, wherein the first connecting pad and the second connecting pad are exposed by the contact holes; and
an upper patterned conductive layer disposed on the planarization structure, the upper patterned conductive layer is filled into the contact holes, and the upper patterned conductive layer is electrically connected to the first connecting pad and the second connecting pad of the chip.

To achieve the above-mentioned objective, another method of fabricating a chip package is provided. The method of fabricating a chip package includes:
providing a package substrate, and forming a plurality of concave chip mounting areas on an upper surface of the package substrate;
forming a lower patterned conductive layer on the upper surface of the package substrate, wherein the lower patterned conductive layer comprises a plurality of first lower patterned conductive layers and a plurality of second lower patterned conductive layers;
providing a plurality of chips, each of the chips comprising:
   a conductive substrate;
   an element disposed on the conductive substrate; and
   a first connecting pad disposed on an upper surface of the element;
mounting a lower surface of the conductive substrate of each of the chips within each of the chip mounting areas, and electrically connect the conductive substrate of each of the chips to each of the second lower patterned conductive layer;
forming a planarization structure on the package substrate and the chips, and further forming a plurality of contact holes on the planarization structure, wherein a portion of the first connecting pad of each of the chips and the first lower patterned conductive layers are exposed by the contact holes; and
forming an upper patterned conductive layer on the planarization structure, and the upper patterned conductive layer is filled into the contact holes, so that each of the first lower patterned conductive layers of the lower patterned conductive layer is electrically connected to the first connecting pad of each of the chips via the upper patterned conductive layer.

To achieve the above-mentioned objective, another chip package is further provided. The chip package includes:
a package substrate comprising at least a concave chip mounting area disposed on an upper surface of the package substrate;
a lower patterned conductive layer disposed on the upper surface of the package substrate, wherein the lower patterned conductive layer comprises at least a first lower patterned conductive layer and at least a second lower patterned conductive layer;
at least a chip disposed in the chip mounting area, wherein the chip comprises:
   a conductive substrate disposed on the second lower patterned conductive layer;
   an element disposed on the conductive substrate; and
   a first connecting pad disposed on an upper surface of the element;
a planarization structure, having a planar surface, disposed on the package substrate, the chip and the lower patterned conductive layer, the planarization structure comprising a plurality of contact holes, wherein the first connecting pad and the first lower patterned conductive layer are exposed by the contact holes; and
an upper patterned conductive layer disposed on the planarization structure, the upper patterned conductive layer is filled into the contact holes, so that the first lower patterned conductive layer of the lower patterned conductive layer is electrically connected to the first connecting pad of the chip via the upper patterned conductive layer.

Since a semiconductor substrate is utilized as the package substrate in the chip package of the present invention, heat dissipation efficiency may be enhanced. Additionally, a planarization structure is disposed in the chip package of the present invention; therefore a planar patterned conductive layer may be formed on the planarization structure, which facilitates the electrical connection between LED chips in series/in parallel.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic view of a conventional LED chip package utilizing leadframe as a package substrate.

FIG. 2 is a schematic view of another conventional LED chip package utilizing PCB as a package substrate.

FIG. 3 to FIG. 10 are schematic views of a method of making a chip package according to a preferred embodiment of the present invention.

FIG. 11 is a schematic view illustrating electrical connection of a plurality of chips in series in the present invention.

FIG. 12 is a schematic view illustrating electrical connection of a plurality of chips in parallel in the present invention.

FIG. 13 to FIG. 19 are schematic views of a method of making a chip package according to another preferred embodiment of the present invention.

FIG. 20 is a schematic view illustrating electrical connection of a plurality of chips in series according to another preferred embodiment of the present invention.

FIG. 21 and FIG. 22 are schematic views illustrating electrical connection of a plurality of chips in parallel according to another preferred embodiment of the present invention.

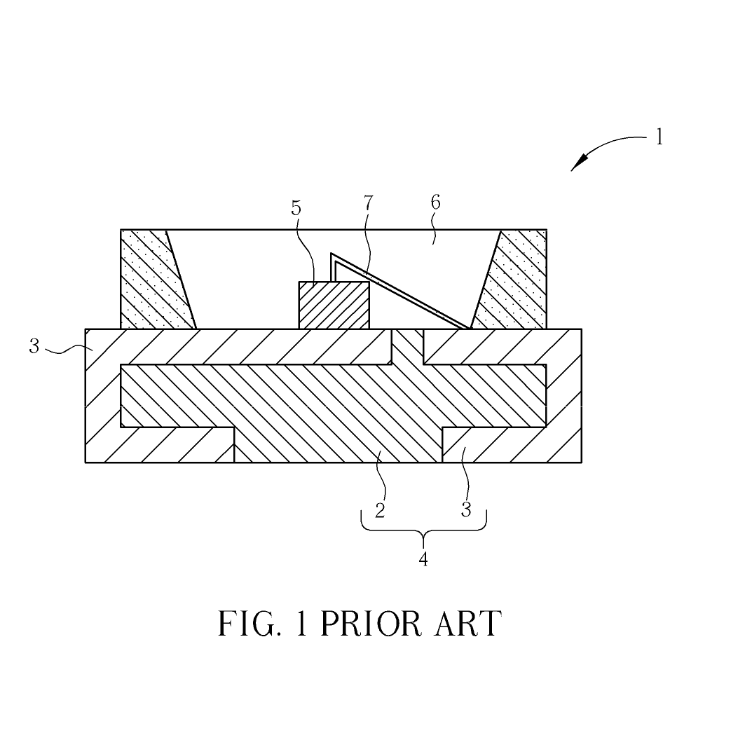

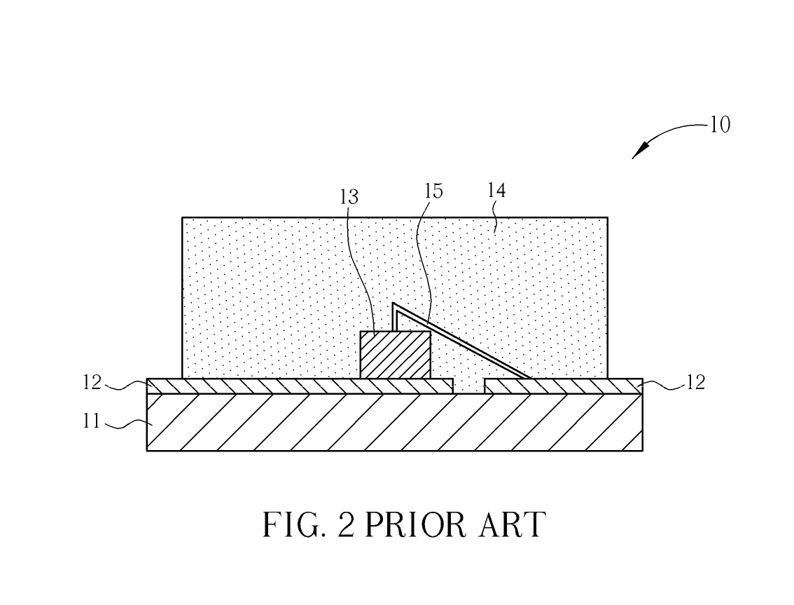

### DETAILED DESCRIPTION

To provide a better understanding of the presented invention, preferred embodiments will be made in details. The preferred embodiments of the present invention are illustrated in the accompanying drawings with numbered elements.

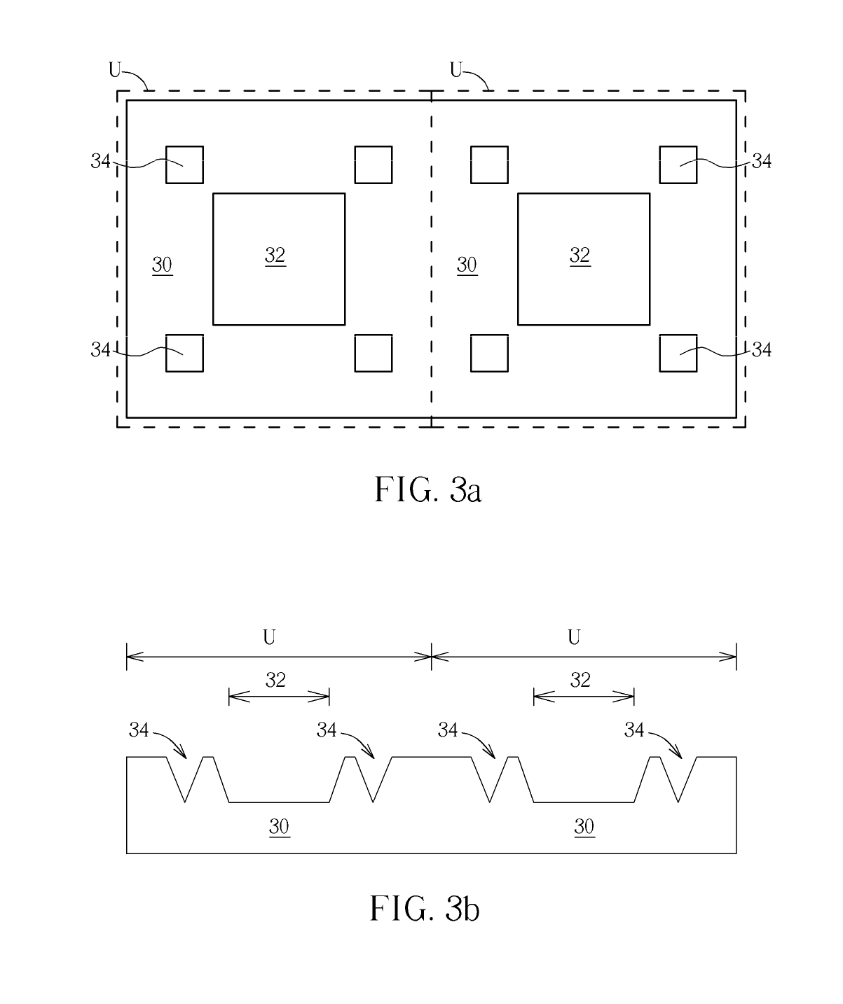

Please refer to FIG. 3 to FIG. 10. FIG. 3 to FIG. 10 are schematic views of a method of making a chip package according to a preferred embodiment of the present invention. FIG. 3a to FIG. 10a are either top views or bottom views, while FIG. 3b to FIG. 10b and FIG. 4c are cross-sectional views. As shown in FIG. 3a and FIG. 3b, a package substrate 30 having a plurality of units U defined thereon is provided at first. In the present embodiment, the thickness of the package substrate 30 is about 1000 micrometers (μm), but is not limited. The package substrate 30 may be a semiconductor substrate, for instance a silicon substrate, gallium arsenide (GaAs) substrate, or other substrates with good heat conductivity, suitable for batch production (large scale production), and compatible with semiconductor fabrication process. Next, a plurality of concave chip mounting areas 32 are formed on the upper surface of the package substrate 30 by photolithography and etching technique. Each of the chip mounting areas 32 is substantially located in the middle of the corresponding unit U, and the area of the chip mounting areas 32 is substantially half of the area of the unit U, but not limited. In the present embodiment, it is preferred to use silicon substrate as the package substrate 30 for its (1,0,0) lattice structure, for instance. When the silicon substrate has (1,0,0) lattice structure, an anisotropic wet etching process using potassium hydroxide (KOH) solution, tetramethylammonium hydroxide (TMAH) solution or ethylenediamine pyrocatechol (EDP) solution as etchant solution may be used. The etching would proceed along the direction of the lattice structure, such that the chip mounting areas 32 may have an outwardly-inclined side wall, which has an included angle of substantially 54.7 degrees with the bottom of the chip mounting areas 32. The outwardly-inclined side wall is beneficial to the fabrication of the conductive wire layer to be formed later on. The above mentioned etching process is not limited to anisotropic wet etching process and may be other wet etching process or dry etching process. The included angle of the side wall and the bottom of the chip mounting areas 32 is not limited to 54.7 degrees and may be adjusted to meet other requirements. In addition, the depth of the chip mounting areas 32 is close to the thickness of the LED chip to be mounted within the chip mounting areas 32. Thus, the depth of the chip mounting areas 32 may vary depending on the thickness of the LED chip, and lies e.g. from several tens to several hundreds of micrometers. For instance, the preferred depth of the chip mounting areas 32 is in between 50 μm to 200 μm, but is not limited to the above mentioned range.

In the chip package of the present invention, the chip may be selectively electrically connected to the lower surface of the package substrate 30 via through holes of the package substrate 30, so as to facilitate external electrical connection. Thus, a step of fabricating through holes may be included in the present method. The step is detailed as follows. In the present embodiment, the through holes of the package substrate 30 includes upper through holes and lower through holes conducting to each other. The upper through holes are fabricated by means of various types of dry or wet etching techniques from the upper surface of the package substrate 30, while the lower through holes corresponding to the upper through holes are fabricated by means of various types of dry or wet etching techniques from the lower surface of the package substrate 30. The step of fabricating the upper through holes includes performing an etching process to form a plurality of upper through holes 34 on the upper surface of the package substrate 30. The side wall of the upper through holes 34 is preferably outwardly inclined so as to facilitate successive fabrication of the conductive wire, but not limited. The etching process of fabricating the upper through holes 34 may be integrated into the etching process of fabricating the chip mounting areas 32. In other words, the chip mounting areas 32 and the upper through holes 34 may be simultaneously formed in the same photolithography and etching process. Since the size of the upper through holes 34 is smaller than the size of the chip mounting areas 32, each of the upper through holes 34 looks like a cone-shaped holes as shown in FIG. 3b.

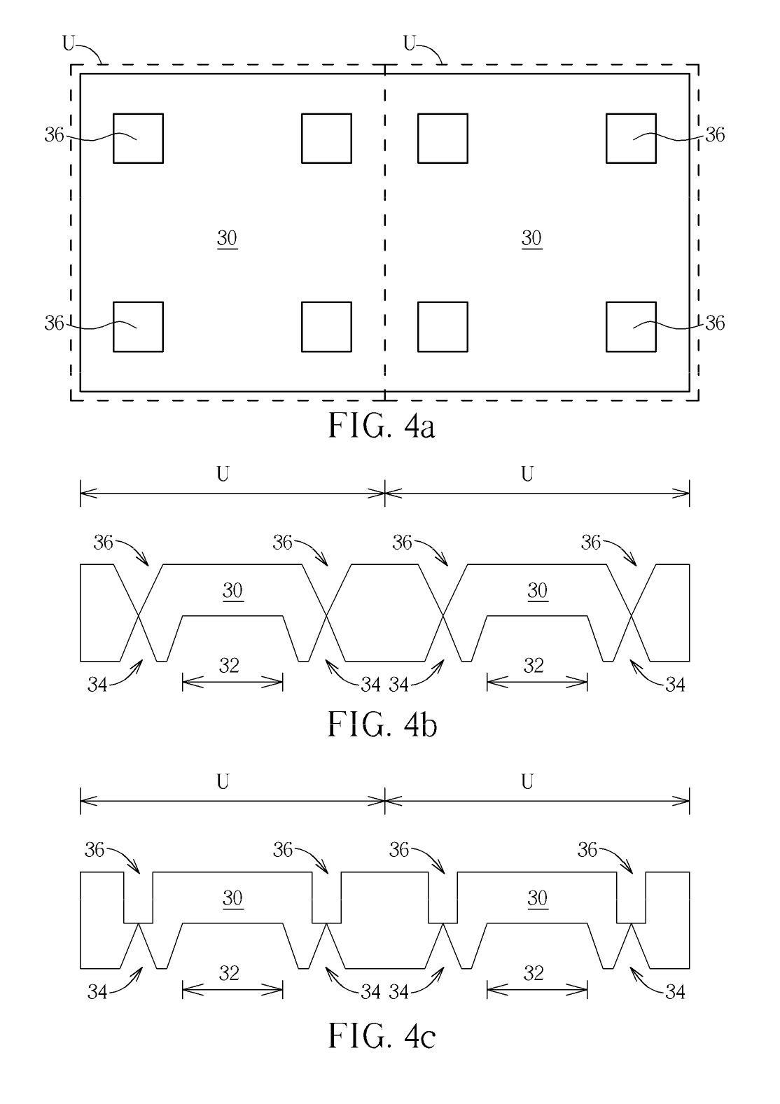

As shown in FIG. 4a and FIG. 4b, a plurality of lower through holes 36 are formed on the lower surface of the package substrate 30 corresponding to the location of the upper through holes 34 by photolithography and etching technique. The steps of forming the upper through holes 34 and the lower through holes 36 are not limited to be in particular order and may be altered according to the requirements of processes. Each of the lower through holes 36 may have similar shapes as the upper through holes 34, and form a through hole that penetrate through the package substrate 30 with the corresponding upper through hole 34. The depth of the lower through holes 36 and the size of the lower through holes 36 are deeper than the depth of the upper through holes 34 and the size of the upper through holes 34 in FIG. 4a and FIG. 4b, but not limited. The depth and size of the upper through holes 34 and the lower through holes 36 may be adjusted according to the depth and size specification of the chip mounting areas 32 or other requirements. In the present embodiment, the lower through holes 36 may also be formed by the above mentioned anisotropic wet etching process, but not limited. In addition, each of the through holes is not limited to be formed by an upper through hole 34 and a lower through hole 36, it may be other structure or formed by other methods. For instance, the lower through holes 36 may have vertical side walls as shown in FIG. 4c formed by an anisotropic wet etching process. In comparison with the lower through holes 36 having the inclined side walls, the lower through holes 36 having vertical side walls are smaller in size, which may lead to increase of integration. The trough holes may also be formed by directly etching through the package substrate 30 from either the upper surface or the lower surface of the package substrate 30.

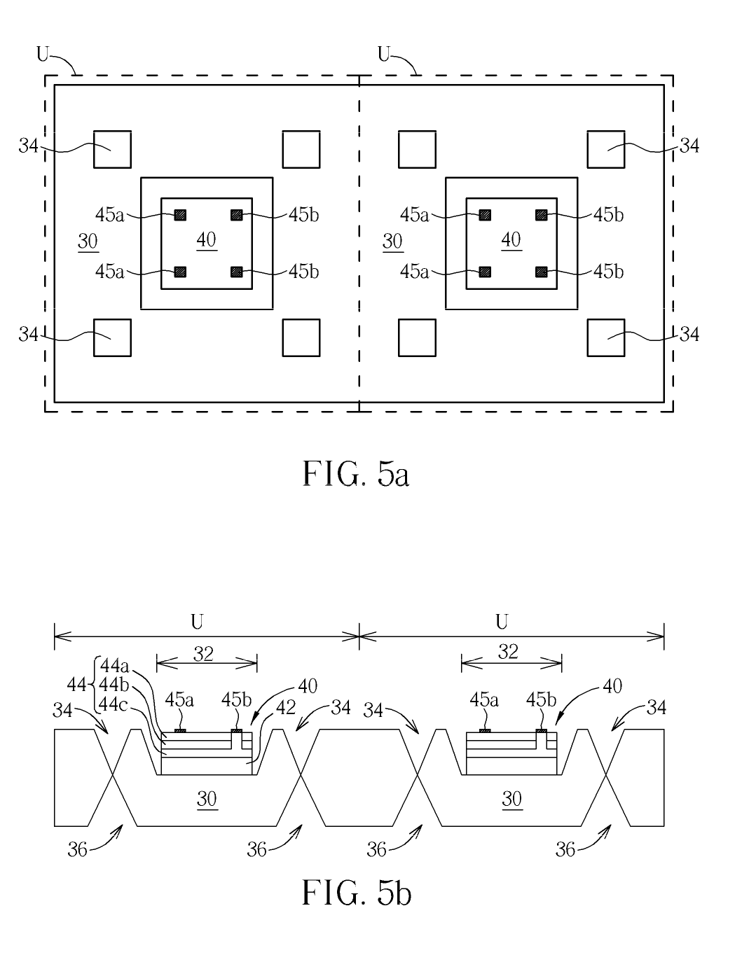

As shown in FIG. 5a and FIG. 5b, a plurality of chips 40 are later on provided. In the present embodiment of the present invention, LED chips are used as an example of the chips 40, but not limited. The chips 40 may be any other types of chips, such as the IC chips or the MEMS chips. The LED chips in the present embodiment is a horizontal type chip, including an element substrate 42, an element 44 formed on the element substrate 42, at least a first connecting pad 45a and at least a second connecting pad 45b disposed on the upper surface of the element 44. A light emitting element is used as the element 44 in the present embodiment. The element 44 includes a second conductive type doped semiconductor layer 44c at the bottom, a light emitting layer 44b, and a first conductive type doped semiconductor layer 44a disposed onto the second conductive type doped semiconductor layer 44c, respectively, in a sequential order. The first connecting pad 45a and the first conductive type doped semiconductor layer 44a are electrically connected to each other, while the second connecting pad 45b is electrically connected to the second conductive type doped semiconductor layer 44c. Preferably, the LED chips in the present embodiment are blue light LED chips, and may collocate with a fluorescent layer that may produce yellow light successively to form white light by light-mixing. Therefore, the materials of the light emitting layer 44b may be semiconductor material that may emit blue light such as gallium nitride (GaN), and the material of the doped semiconductor layer may be GaN or other appropriate materials. The LED chips are not limited to be blue light LED chips, and may be other suitable LED chips, made of suitable material, that meet other requirements. In the present embodiment, the first conductive type doped semiconductor layer 44a is a P-type doped semiconductor layer, and the second conductive type doped semiconductor layer 44c is an N-type doped semiconductor layer, but not limited. In addition, to increase the efficiency of light extraction of the LED chips, micro-protrusions may further be fabricated on the surface of the element substrate 42 or the first conductive type doped semiconductor layer 44a. Besides, in order to increase the illumination efficiency or meet other requirements, the LED chips may further include other film layers such as injection layers or transport layers. Next, a chip mounting process is carried out. The element substrate 42 of each of the chips 40 is mounted onto each of the chip mounting areas 32 on the package substrate 30. As previously described, the thickness of the chips 40 (including the element substrate 42) and the depth of the chip mounting areas 32 and are close, and thus the package substrate 30 and the upper surface of the chips 40 are substantially in the same plane, leaving only spaces in between the periphery of the chips 40 and the chip mounting areas 32.

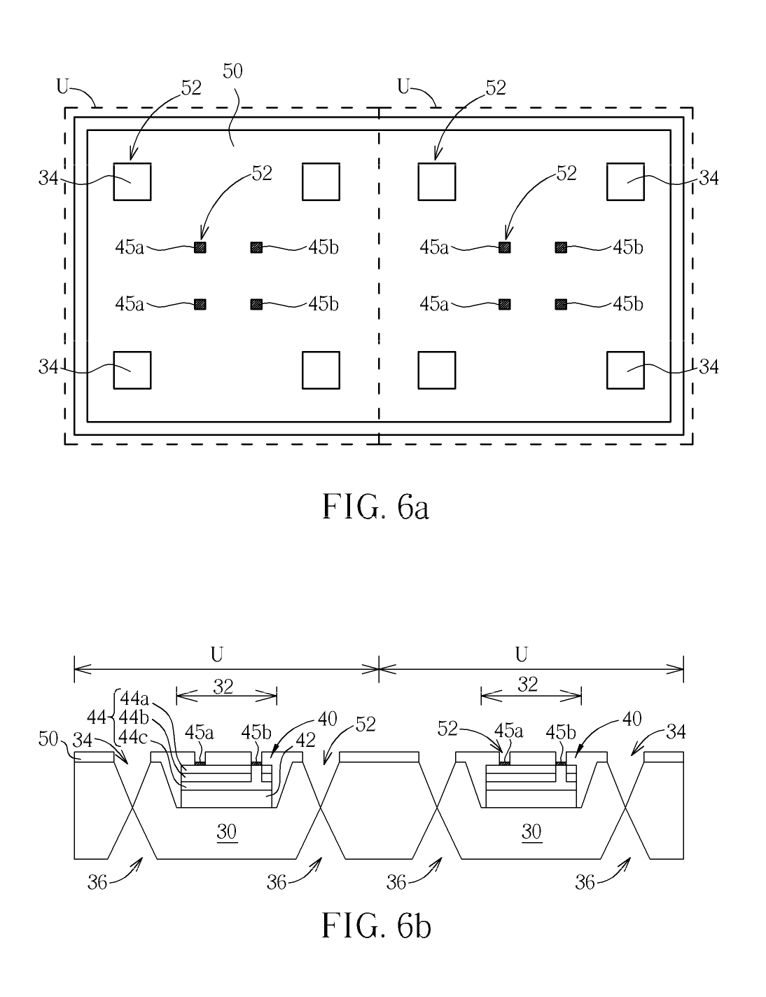

As shown in FIG. 6a and FIG. 6b, a planarization structure 50 is formed on the package substrate 30 and the chips 40. The planarization structure 50 is dielectric and is filled into the spaces between the chips 40 and the chip mounting areas 32, as a result, a complete plane is formed on the package substrate 30 and the upper surface of the chips 40, which makes it easy to form successive conductive wires thereon. Subsequently, a plurality of contact holes 52 are formed on the planarization structure 50, wherein the first connecting pad 45a and the second connecting pad 45b of each of the chips 40 are exposed by the contact holes 52. Since the electricity of the chip package of the present embodiment may be conduct to the lower surface of the package substrate 30 via the through holes of the package substrate 30, the upper through holes may be exposed by the planarization structure 50. In the present embodiment, the planarization structure 50 may be made of photosensitive material (such as photoresist), which may be formed by spin coating and patterned by exposure and development technique. However, the material and the formation of the planarization structure 50 are not limited. For instance, the planarization structure 50 may be made of other materials and may be patterned by photolithography and etching technique.

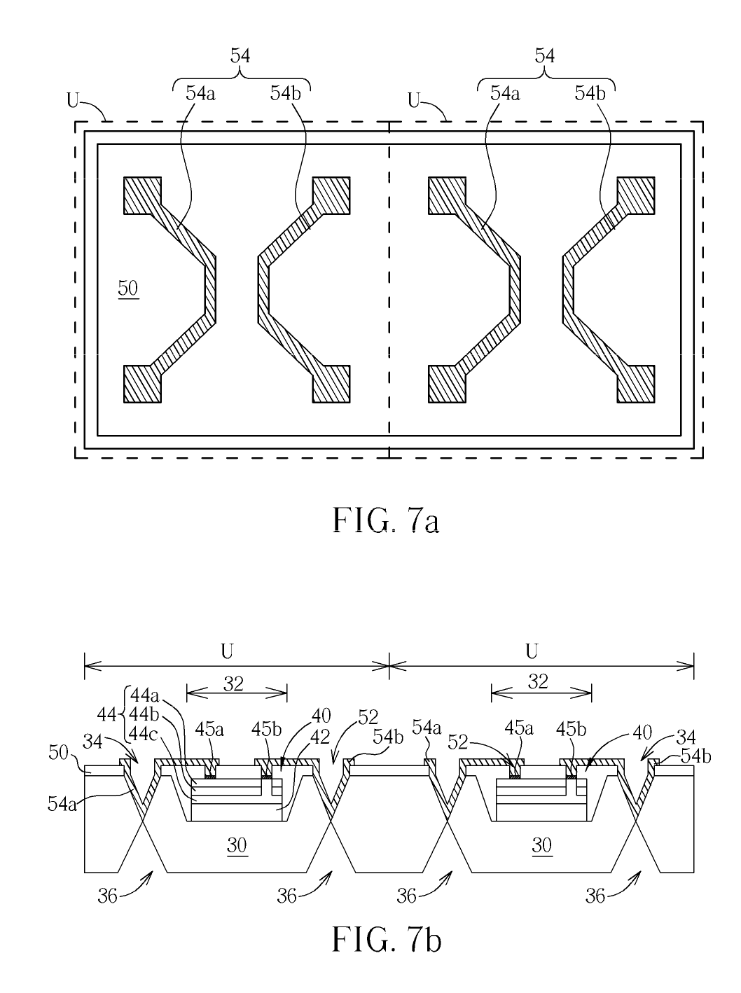

As shown in FIG. 7a and FIG. 7b, an upper patterned conductive layer 54 is formed on the planarization structure 50. The upper patterned conductive layer 54 is filled into the contact holes 52. The upper patterned conductive layer 54 includes a plurality of first upper patterned conductive layers 54a and a plurality of second upper patterned conductive layers 54b. The first upper patterned conductive layers 54a and the second upper patterned conductive layers 54b are electrically disconnected to each other. Within each of the units U, the first upper patterned conductive layers 54a is filled into a portion of the contact holes 52, so that the first connecting pad 45a of the chips 40 is electrically connected to a portion of the upper through holes 34; while the second upper patterned conductive layers 54b is filled into another portion of the contact holes 52, so that the second connecting pad 45b of the chips 40 is electrically connected to another portion of the upper through holes 34. The function of the upper patterned conductive layer 54 is to serve as the conductive wire. Thus, the material may be any single material or a complex material with good electrical conductivity, and the upper patterned conductive layer 54 may be formed by any kinds of thin film technologies depending on the selected material. In addition, the upper patterned conductive layer 54 may have different pattern designs according to the requirements, and not limited to the patterns shown in the figures.

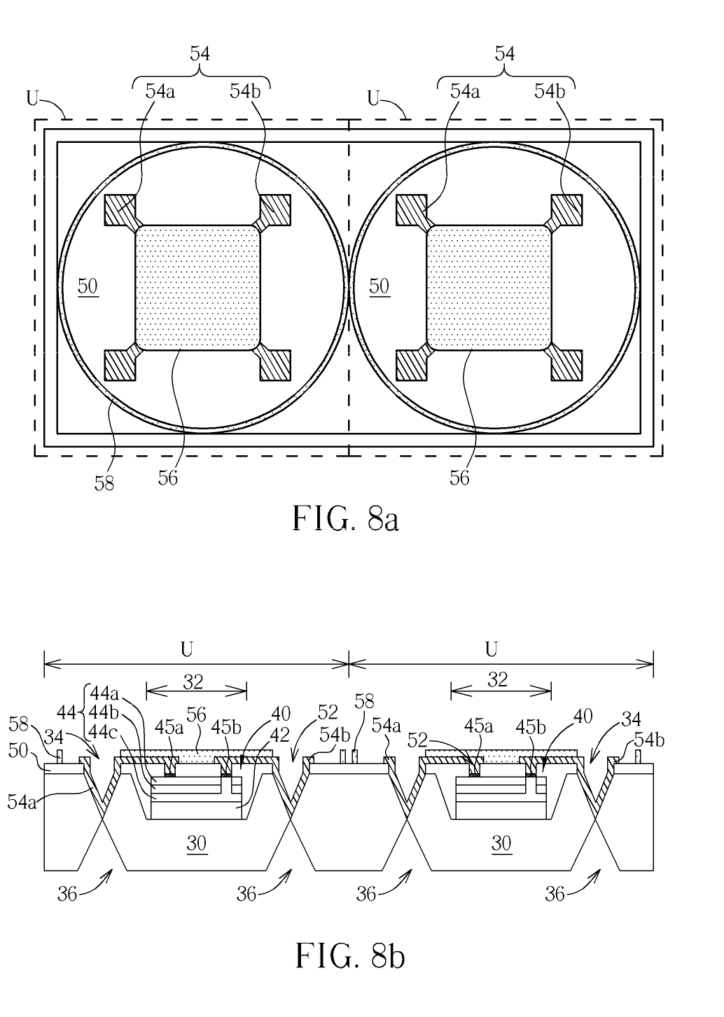

As shown in FIG. 8a and FIG. 8b, a plurality of fluorescent patterns 56 are formed on the planarization structure 50 and the upper patterned conductive layer 54. Each of the fluorescent patterns 56 is located within each unit U and is substantially corresponding to each of the chip mounting areas 32. The function of the fluorescent patterns 56 is to transform a portion of the light emitted by the LED chips into the light of another color. For instance, the LED chips in the present embodiment are blue light LED chips, thus fluorescent materials able to generate yellow light may be used as the fluorescent patterns 56. White light may therefore be produced by mixing blue light and yellow light. The fluorescent patterns 56 may be made of photosensitive material doped with fluorescent powder, and formed by lithography and etching technique, but the material and fabrication are not limited. In addition, a plurality of closed circular patterns 58 are formed on the planarization structure 50, and each of the closed circular patterns 58 surrounds each of the chip mounting areas 32. The closed circular patterns 58 have a certain thickness, for instance, several micrometers, and the closed circular patterns 58 have different surface characteristics from the planarization structure 50, for example one is hydrophilic and the other is hydrophobic. The function of the closed circular patterns 58 is to maintain the surface tension of the encapsulation to be formed subsequently. The surface tension renders the encapsulation to have a hemisphere shape, and the hemisphere shape enables the encapsulation to be an optical lens. In the present embodiment, the closed circular patterns 58 and the fluorescent patterns 56 are preferably made of the same photosensitive material, and formed by the same lithography exposure and development process. In such a manner, the fabrication is simplified. However, this is not a limitation of the method in the present invention.

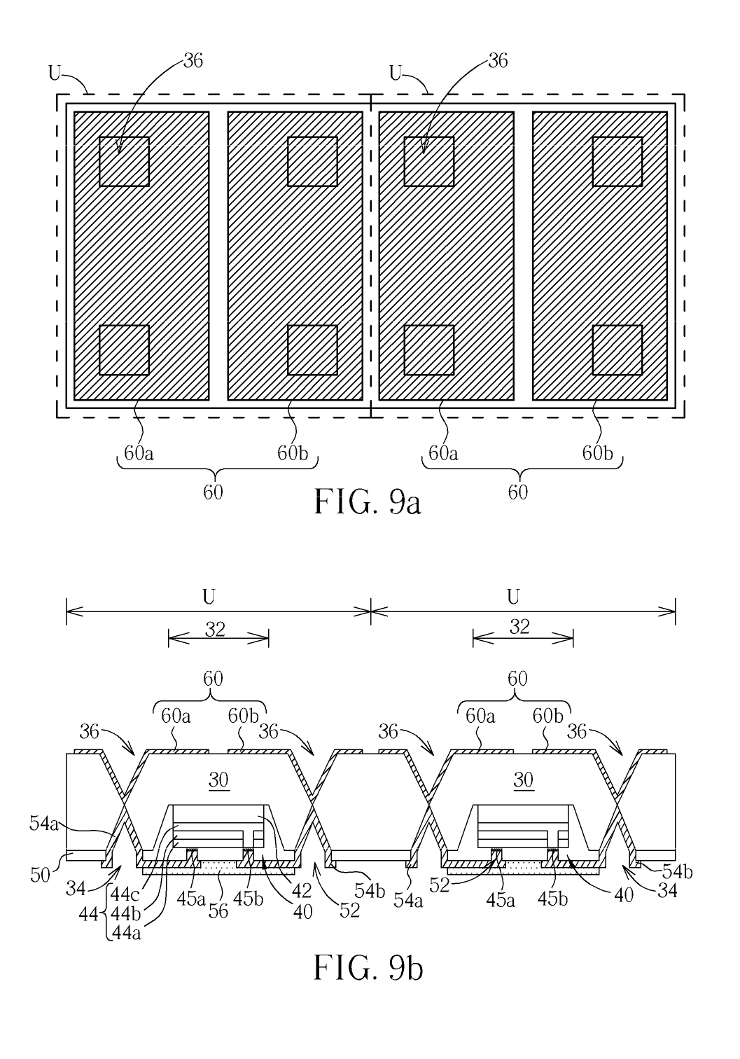

As shown in FIG. 9a and FIG. 9b, since the external electrical connection of the chip package of the present embodiment may be fulfilled on the lower surface of the package substrate 30, the method in the present invention may include the step of fabricating a back patterned conductive layer. The step of fabricating the back patterned conductive layer is not limited in particular order, and may be altered according to different process requirements. The step of fabricating the back patterned conductive layer is detailed as follows. A back patterned conductive layer 60 is formed on the lower surface of the package substrate 30, and filled into the lower through holes 36. The back patterned conductive layer 60 includes a plurality of first back patterned conductive layers 60a and a plurality of second back patterned conductive layers 60b. In each of the unit U, the first back patterned conductive layer 60a and the second back patterned conductive layer 60b are electrically disconnected. Each of the first back patterned conductive layer 60a is filled into a portion of the lower through holes 36 and is therefore electrically connected to the first upper patterned conductive layer 54a filled in the corresponding upper through holes 34. Each of the second back patterned conductive layers 60b is filled into the other lower through holes 36 and is therefore electrically connected to the second upper patterned conductive layer 54b filled in the corresponding upper through holes 34. Accordingly, the connecting terminals of the LED chips may be transferred from the upper surface to the lower surface of the package substrate 30 via the design of the through holes and the back patterned conductive layer 60. This facilitates the implementation of external electrical connection to be done subsequently. In addition, the heat produced by the LED chips during light emission will be downwardly conducted to the bottom directly through the package substrate 30, and dissipated. The electricity of the LED chips is transferred to the back patterned conductive layer 60 via the upper patterned conductive layer 54 and the through holes located in the periphery of the chip mounting areas 32. The design of separating the transmission of heat and electricity is in favor of enhancing the heat dissipation effect and the illumination efficiency of the LED chips.

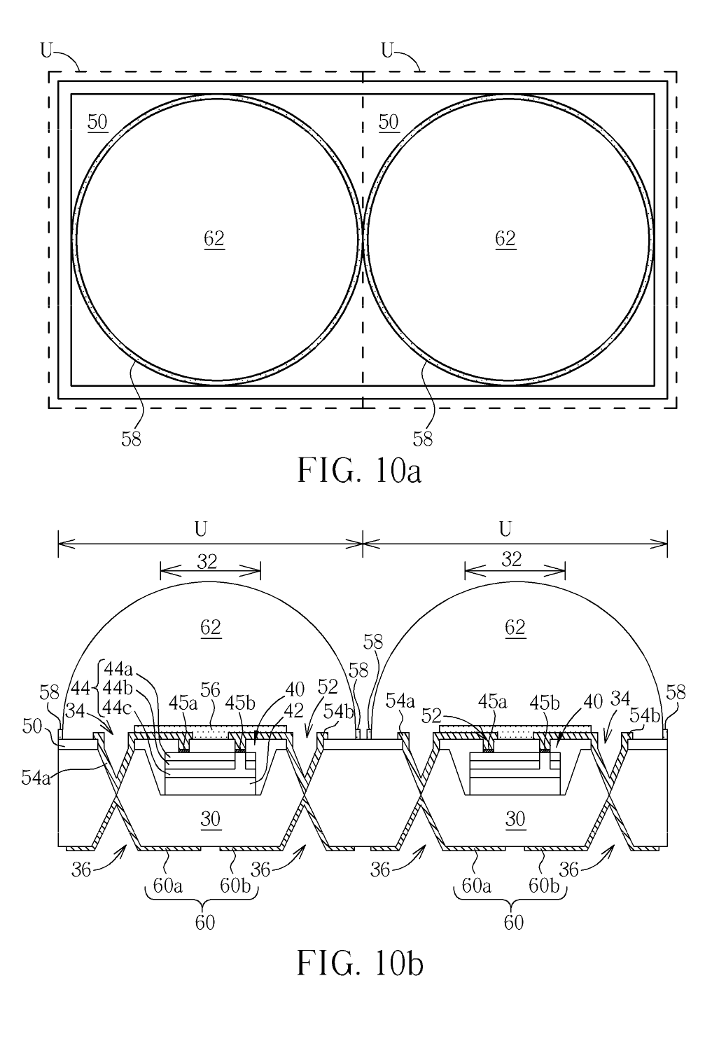

As shown in FIG. 10a and FIG. 10b, a glue dispensing process is then performed. An encapsulation 62 is formed on each of the fluorescent patterns 56 within each unit U. The surface tension of the encapsulation 62 is maintained by the existence of the closed circular pattern 58, and the shape of the encapsulation 62 becomes hemisphere. The encapsulation 62 will form an optical lens after solidified. Subsequently, a segmentation process is performed to form a plurality of chip packages.

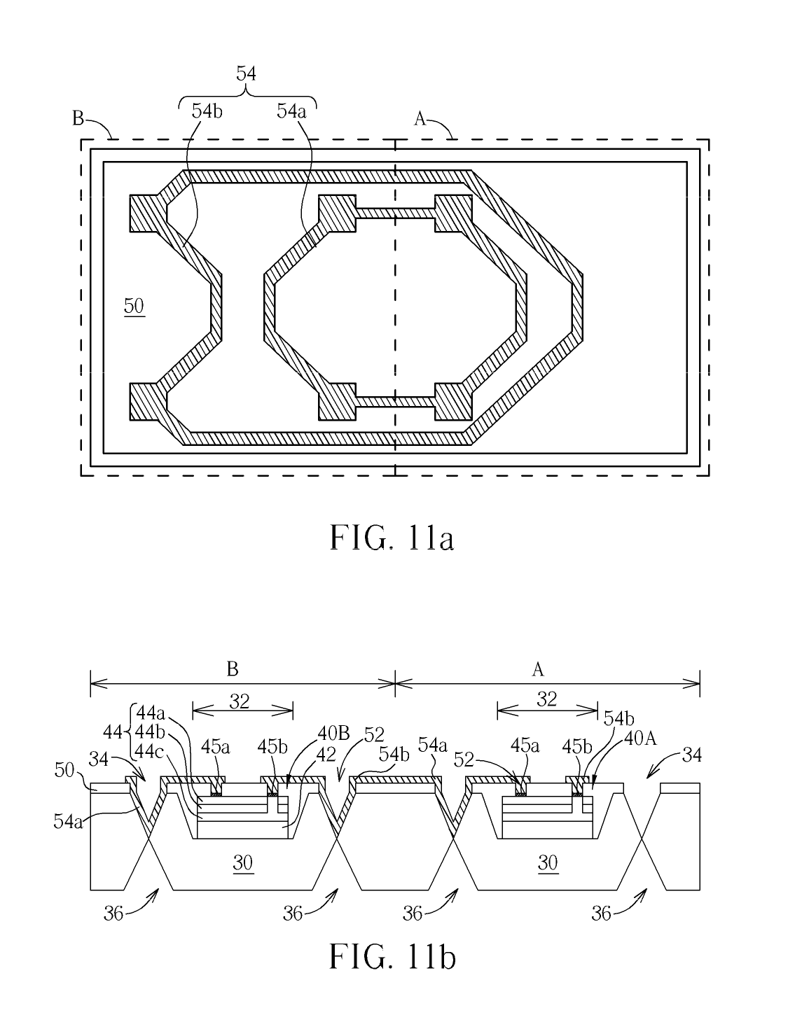

The planarization structure 50 in the chip package of the present invention enables fabrication of the planar upper patterned conductive layer 54 formed by planar technique. The planar upper patterned conductive layer 54 of the present invention is able to implement electrical connection between multiple LED chips by altering the patterns of the upper patterned conductive layer 54 and the contact holes 52 of the planarization structure 50. Please refer to FIG. 11. FIG. 11 is a schematic view illustrating electrical connection of a plurality of chips in series in the present invention. FIG. 11a is a top view, while FIG. 11b is a cross-sectional view. The serial electrical connection of the chips 40 are realized by redesigning the pattern of the planarization structure 50 and the upper patterned conductive layer 54, and an example of connecting two adjacent chips 40 (namely first chip 40A and second chip 40B) in series is illustrated as follows. As shown in FIG. 11a and FIG. 11b, a plurality of contact holes 52 are formed in the planarization structure 50, each exposing the first connecting pad 45a of the first chip 40A and the second connecting pad 45b of the second chip 40B, respectively, and also exposing the upper through holes 34. Later, the upper patterned conductive layers 54 is formed on the planarization structure 50. The first upper patterned conductive layers 54a of the upper patterned conductive layers 54 is filled into the contact holes 52 corresponding to the first connecting pad 45a of the unit A and the contact holes 52 corresponding to the second connecting pad 45b of the unit B. In addition, the electricity of the first connecting pad 45a of unit A and that of the second connecting pad 45b of unit B are connected within a portion of the upper through holes 34. The second upper patterned conductive layers 54b of the upper patterned conductive layers 54 is filled into the contact holes 52 corresponding to the second connecting pad 45b of unit A and the contact holes 52 corresponding to the first connecting pad 45a of the unit B. The electricity of the second connecting pad 45b of unit A and the first connecting pad 45a of the unit B are further connected within another portion of the upper through holes 34. Therefore, the first chips 40A of the unit A and the second chips 40B of the unit B is connected in series. In this embodiment, two chips are illustrated as an example, but the number of the chips to be electrically connected in series is not limited and may be altered according to different requirements. Moreover, if the disposition of the chips 40 is altered, for instance the location of the first connecting pad 45a and the second connecting pad 45b of the second chips 40B are switched, the method in the present embodiment may result in parallel electrical connection.

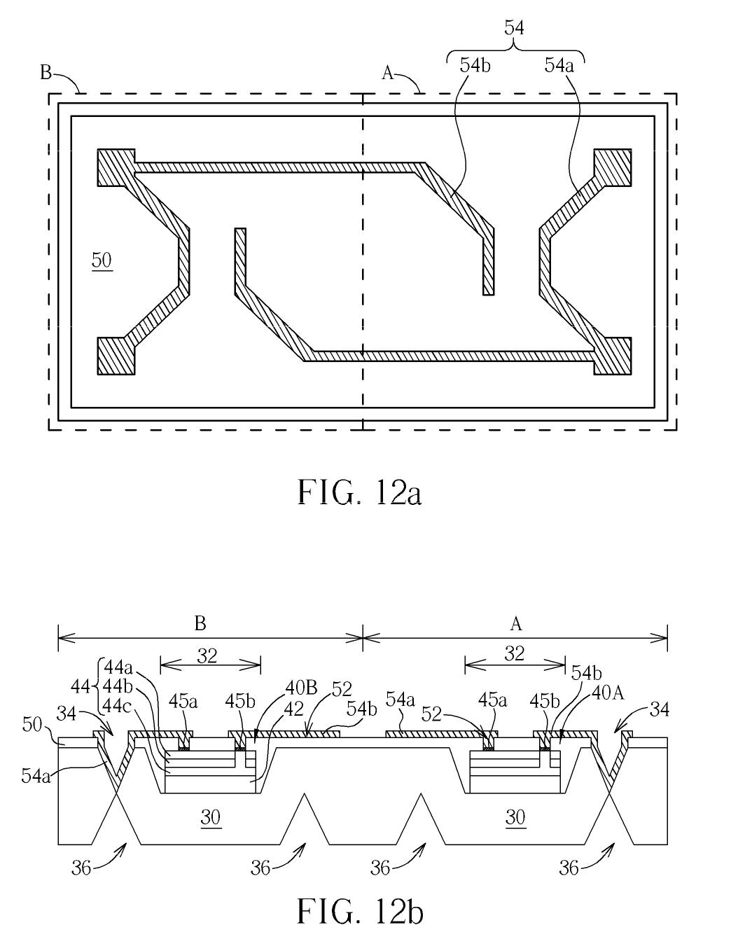

Please refer to FIG. 12. FIG. 12 is a schematic view illustrating electrical connection of a plurality of chips in parallel in the present invention. FIG. 12a is a top view, while FIG. 12b is a cross-sectional view. The parallel electrical connection of the chips 40 are realized by redesigning the pattern of the planarization structure 50 and the upper patterned conductive layer 54, and an example of electrically connecting two adjacent chips 40 (namely first chip 40A and second chip 40B) in parallel is illustrated as follows. As shown in FIG. 12a and FIG. 12b, a plurality of contact holes 52 are formed in the planarization structure 50, each exposing the first connecting pad 45a of the first chip 40A and the second connecting pad 45b of the second chip 40B, respectively, and also exposing the upper through holes 34. Later, the upper patterned conductive layer 54 is formed on the planarization structure 50. The first upper patterned conductive layers 54a of the upper patterned conductive layers 54 is filled into the contact holes 52 corresponding to the first connecting pad 45a of the unit A and the contact holes 52 corresponding to the first connecting pad 45a of the unit B. In addition, the electricity of the first connecting pad 45a of unit A and that of the first connecting pad 45a of unit B are connected within a portion of the upper through holes 34. The second upper patterned conductive layers 54b of the upper patterned conductive layers 54 is filled into the contact holes 52 corresponding to the second connecting pad 45b of unit A and the contact holes 52 corresponding to the second connecting pad 45b of the unit B. The electricity of the second connecting pad 45b of unit A and the second connecting pad 45b of the unit B are further connected within another portion of the upper through holes 34. Therefore, the first chips 40A of the unit A and the second chips 40B of the unit B is connected in parallel. In this embodiment, two chips are illustrated as an example, but the number of the chips to be electrically connected in parallel is not limited and may be altered according to different requirements. Moreover, if the disposition of the chips 40 is altered, for instance the location of the first connecting pad 45a and the second connecting pad 45b of the second chips 40B are switched, the method in the present embodiment may result in serial electrical connection.

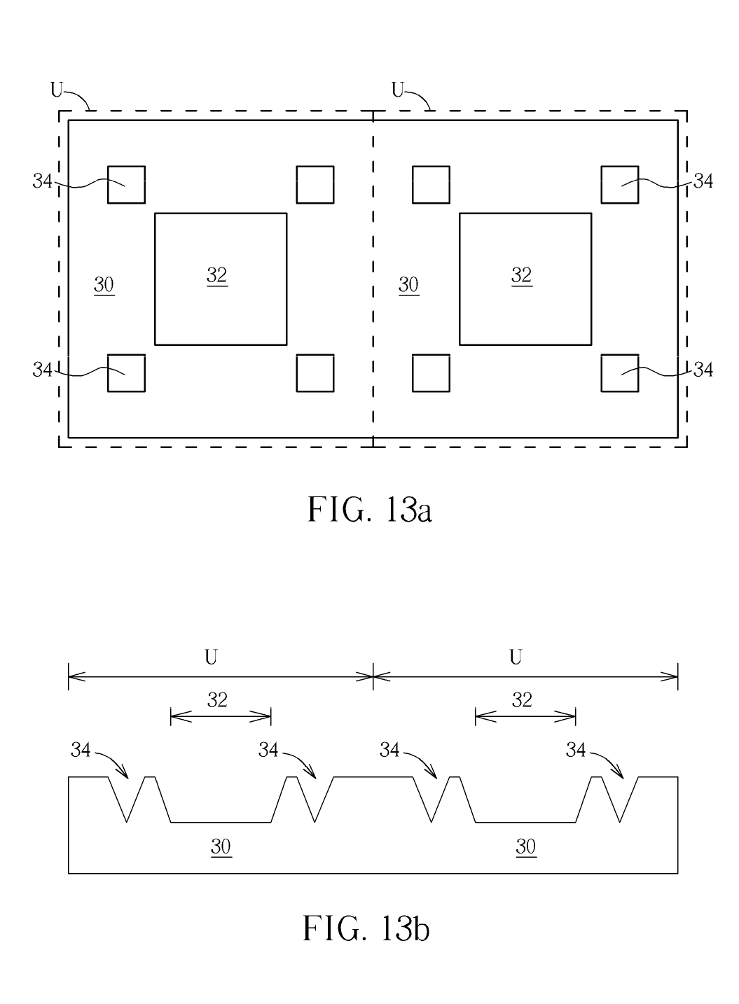

Please refer to FIG. 13 to FIG. 19. FIG. 13 to FIG. 19 are schematic views of a method of making a chip package according to another preferred embodiment of the present invention. FIG. 13a to FIG. 19a are either top views or bottom views, while FIG. 13b to FIG. 19b are cross-sectional views. For comparison of the similarities and dissimilarities of the present embodiment and the previous mentioned embodiment, the numberings of the same elements in the present embodiment are the same as that in the previous mentioned embodiment. As shown in FIG. 13a and FIG. 13b, a package substrate 30 is provided at first. The package substrate 30 may be a semiconductor substrate, for instance a silicon substrate, GaAs substrate, or other substrates with good heat conductivity, suitable for batch production (large scale production), and compatible with semiconductor fabrication process. A plurality of units U are defined on the package substrate 30. The thickness of the package substrate 30 is about 1000 micrometers (μm), but is not limited. A plurality of concave chip mounting areas 32 are then formed on the upper surface of the package substrate 30 by photolithography and etching technique. Each of the chip mounting areas 32 is substantially located in the middle of the corresponding unit U, and the area of the chip mounting areas 32 is substantially half of the area of the unit U, but not limited. In the present embodiment, it is preferred to use silicon substrate as the package substrate 30 for its (1,0,0) lattice structure, for instance. When the silicon substrate has (1,0,0) lattice structure, an anisotropic wet etching process is preferably used. The etching would proceed along the direction of the lattice structure, such that the chip mounting areas 32 may have an outwardly-inclined side wall, which has an included angle of substantially 54.7 degrees with the bottom of the chip mounting areas 32. The outwardly-inclined side wall is beneficial to the fabrication of the conductive wire layer to be formed later on. The above mentioned etching process is not limited to anisotropic wet etching process and may be other wet etching process or dry etching process. The included angle of the side wall and the bottom of the chip mounting areas 32 is not limited to 54.7 degrees and may be adjusted to meet other requirements. In addition, the depth of the chip mounting areas 32 is close to the thickness of the LED chip to be mounted within the chip mounting areas 32. Thus, the depth of the chip mounting areas 32 may vary depending on the thickness of the LED chip, and lies e.g. from several tens to several hundreds of micrometers. For instance, the preferred depth of the chip mounting areas 32 is in between 50 μm to 150 μm, but is not limited to the above mentioned range.

In the chip package of the present invention, the chip may be selectively electrically connected to the lower surface of the package substrate 30 via through holes of the package substrate 30, so as to facilitate external electrical connection. Thus, a step of fabricating through holes may be included in the present method. The step is detailed as follows. In the present embodiment, the through holes of the package substrate 30 includes upper through holes and lower through holes conducting to each other. The upper through holes are fabricated by means of various types of dry or wet etching techniques from the upper surface of the package substrate 30, while the lower through holes corresponding to the upper through holes are fabricated by means of various types of dry or wet etching techniques from the lower surface of the package substrate 30. The step of fabricating the upper through holes includes performing an etching process to form a plurality of upper through holes 34 on the upper surface of the package substrate 30. The side wall of the upper through holes 34 is preferably outwardly inclined so as to facilitate successive fabrication of the conductive wire, but not limited. The etching process of fabricating the upper through holes 34 may be integrated into the etching process of fabricating the chip mounting areas 32. In other words, the chip mounting areas 32 and the upper through holes 34 may be simultaneously formed in the same photolithography and etching process. Since the size of the upper through holes 34 is smaller than the size of the chip mounting areas 32, each of the upper through holes 34 looks like a cone-shaped holes as shown in FIG. 13b.

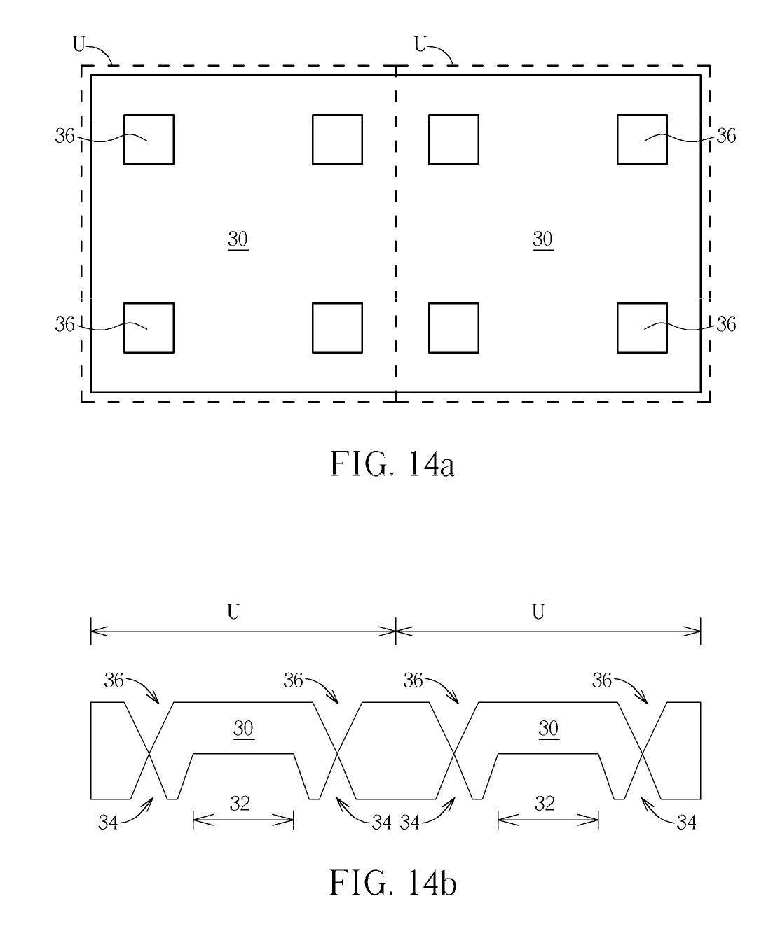

As shown in FIG. 14a and FIG. 14b, a plurality of lower through holes 36 are formed on the lower surface of the package substrate 30 corresponding to the location of the upper through holes 34 by photolithography and etching technique. The steps of forming the upper through holes 34 and the lower through holes 36 are not limited to be in particular order and may be altered according to the requirements of processes. Each of the lower through holes 36 may have similar shapes as the upper through holes 34, and form a through hole that penetrate through the package substrate 30 with the corresponding upper through hole 34. The depth of the lower through holes 36 and the size of the lower through holes 36 are deeper than the depth of the upper through holes 34 and the size of the upper through holes 34 in FIG. 14a and FIG. 14b, but not limited. The depth and size of the upper through holes 34 and the lower through holes 36 may be adjusted according to the depth and size specification of the chip mounting areas 32 or other requirements. In the present embodiment, the lower through holes 36 may also be formed by the above mentioned anisotropic wet etching process, but not limited. In addition, each of the through holes is not limited to be formed by an upper through hole 34 and a lower through hole 36, it may be other structure or formed by other methods. For instance, the through holes may have vertical side walls, and formed by directly etching through the package substrate 30 from either the upper surface or the lower surface of the package substrate 30.

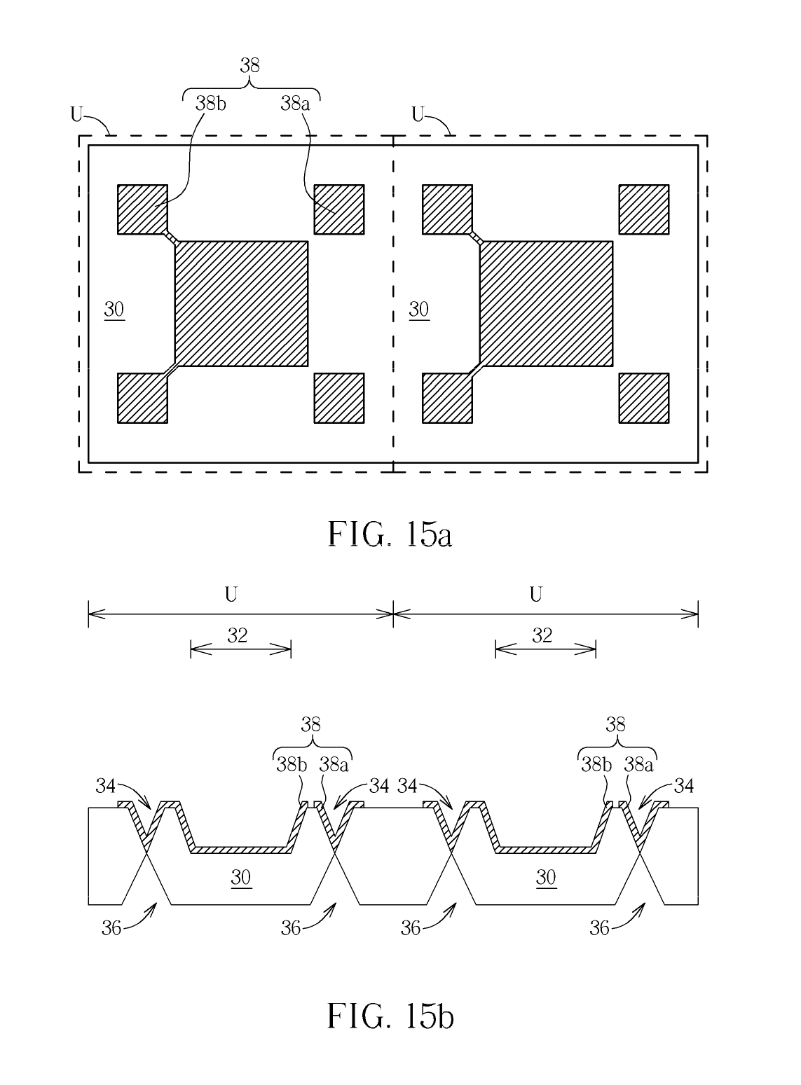

As shown in FIG. 15a and FIG. 15b, a lower patterned conductive layer 38 is formed on the upper surface of the package substrate 30. The lower patterned conductive layer 38 includes a plurality of first lower patterned conductive layers 38a and a plurality of second lower patterned conductive layers 38b. Each of the second lower patterned conductive layers 38b is formed in at least a portion of the corresponding chip mounting area 32 and is extended to fill in a portion of the upper through holes 34 within the corresponding unit U. Each of the first lower patterned conductive layers 38a is not formed in the corresponding chip mounting area 32, and is not electrically connected to the second lower patterned conductive layers 38b, either. Each of the first lower patterned conductive layers 38a, however, is filled into other upper through holes 34 within the corresponding unit U. The lower patterned conductive layer 38 is served as conductive wire. The material of the lower patterned conductive layer 38 may be any single material such as silver, or a complex material such as alloys of gold and tin with good electrical conductivity. The thickness of the lower patterned conductive layer 38 may be 2 μm for example, but is not limited. Furthermore, the fabrication of the lower patterned conductive layer 38 may be carried out by different types of thin film techniques based on the material characteristic. For instance, the lower patterned conductive layer 38 may be formed by electroplating, electroless plating, deposition, etc, and patterned by photolithography and etching technique. In the present embodiment, the external connection of the LED chip is implemented on the lower surface of the package substrate 30 by conveying the electricity of the LED chip to the lower surface of the package substrate 30 via the through holes. Thus, the first lower patterned conductive layers 38a and the second lower patterned conductive layers 38b are filled into different upper through holes 34 within the corresponding unit U. In other embodiments without disposing the through holes, the first lower patterned conductive layers 38a and the second lower patterned conductive layers 38b must stay electrically disconnected.

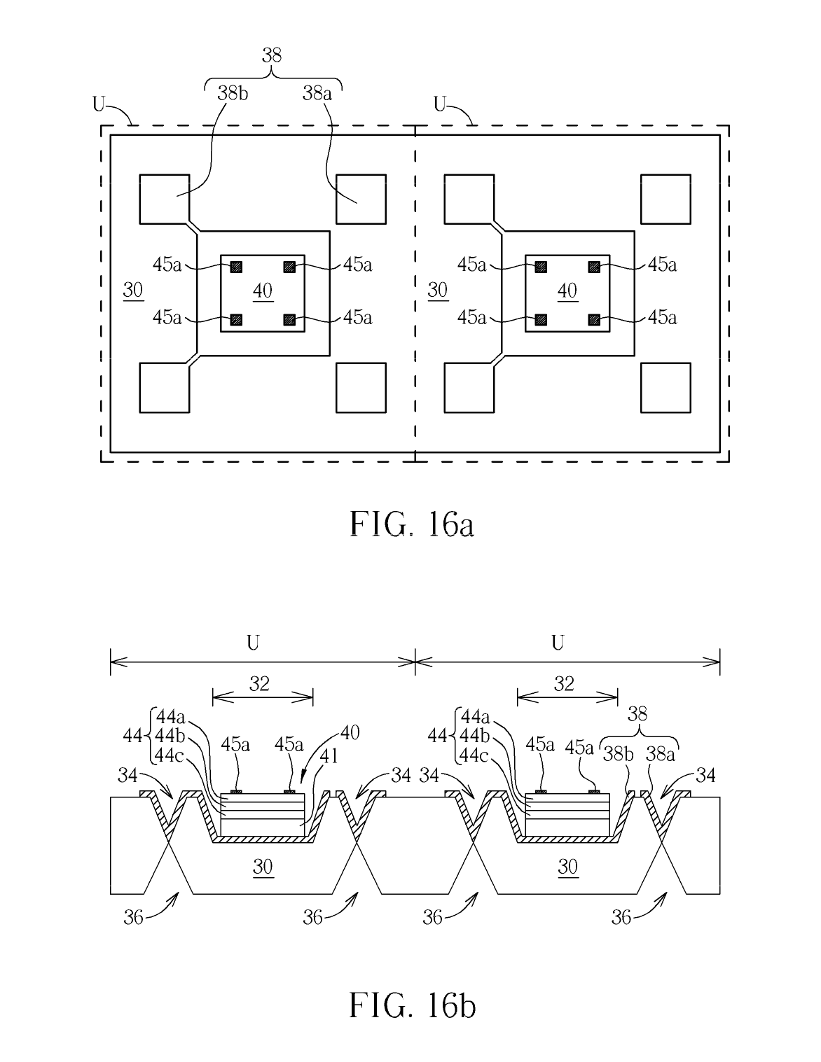

As shown in FIG. 16a and FIG. 16b, a plurality of chips 40 are then provided. In the present embodiment of the present invention, LED chips are used as an example of the chips 40, but not limited. The chips 40 may be any other types of chips, such as the IC chips or the MEMS chips. The LED chips in the present embodiment is a vertical type chip, including a conductive substrate 41, an element 44 disposed on the conductive substrate 41, and at least a first connecting pad 45a disposed on an upper surface of the element 44. A light emitting element is used as the element 44 in the present embodiment. The light emitting element includes a second conductive type doped semiconductor layer 44c at the bottom, a light emitting layer 44b, and a first conductive type doped semiconductor layer 44a disposed onto the second conductive type doped semiconductor layer 44c, respectively, in a sequential order. The first connecting pad 45a is disposed on and is electrically connected to the first conductive type doped semiconductor layer 44a. Preferably, the LED chips in the present embodiment are blue light LED chips, and may collocate with a fluorescent layer that may produce yellow light successively to form white light by light-mixing. Therefore, the materials of the light emitting layer 44b may be semiconductor material that may emit blue light such as GaN, and the material of the doped semiconductor layer may be GaN or other appropriate materials. The LED chips are not limited to be blue light LED chips, and may be other suitable LED chips, made of suitable semiconductor material, that meet other requirements.

In the present embodiment, the first conductive type doped semiconductor layer 44a is a P-type doped semiconductor layer, and the second conductive type doped semiconductor layer 44c is an N-type doped semiconductor layer, but not limited. In addition, to increase the efficiency of light extraction of the LED chips, micro-protrusions may further be fabricated on the surface of the conductive substrate 41 or the first conductive type doped semiconductor layer 44a. Besides, in order to increase the illumination efficiency or meet other requirements, the LED chips may further include other common film layers such as injection layers or transport layers. Next, a chip mounting process is carried out. Each of the chips 40 is mounted onto each of the chip mounting areas 32, such that the conductive substrate 41 of the LED chips is electrically connected to the second lower patterned conductive layers 38b of the lower patterned conductive layer. The conductive substrate 41 is made of electrical conductive material such as the Silicon carbide (SiC), therefore the electricity of the second conductive type doped semiconductor layer 44c may connect to the second lower patterned conductive layers 38b directly via the conductive substrate 41, so as to facilitate external electrical connection. As previously described, the thickness of the chips 40 (including the conductive substrate 41) and the depth of the chip mounting areas 32 and are close, and thus the package substrate 30 and the upper surface of the chips 40 are substantially in the same plane, leaving only spaces in between the periphery of the chips 40 and the chip mounting areas 32.

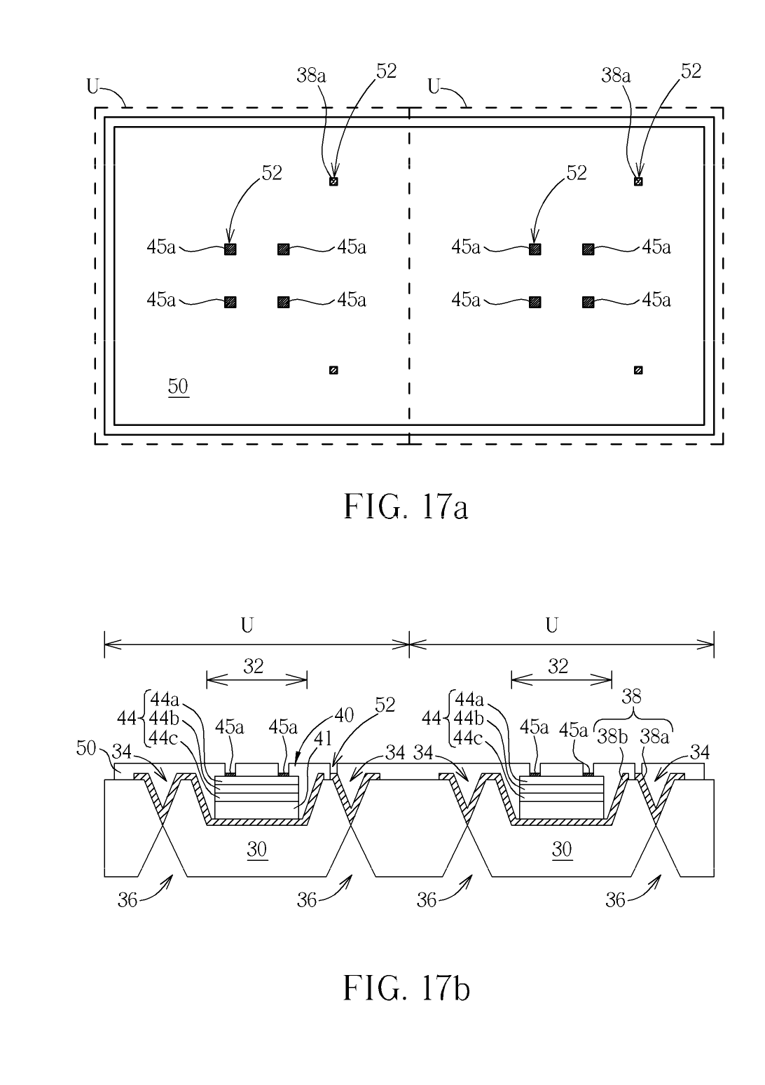

As shown in FIG. 17a and FIG. 17b, a planarization structure 50 is formed on the package substrate 30, the lower patterned conductive layer 38 and the chips 40. The planarization structure 50 is dielectric and is filled into the spaces between the chips 40 and the chip mounting areas 32, and consequently a complete plane is formed on the package substrate 30 and the upper surface of the LED chips, which makes it easy to form successive conductive wires thereon. Subsequently, a plurality of contact holes 52 are formed in the planarization structure 50, wherein first the connecting pad 45a of each of the chips 40 and each of the first lower patterned conductive layers 38a of the lower patterned conductive layer 38 are exposed by the contact holes 52. In the present embodiment, the planarization structure 50 may be made of photosensitive material (such as photoresist), such that the contact holes 52 may be formed by spin coating and patterned by exposure and development technique. However, the material and the formation of the planarization structure 50 are not limited. For instance, the planarization structure 50 may be made of other materials and may be patterned by photolithography and etching technique.

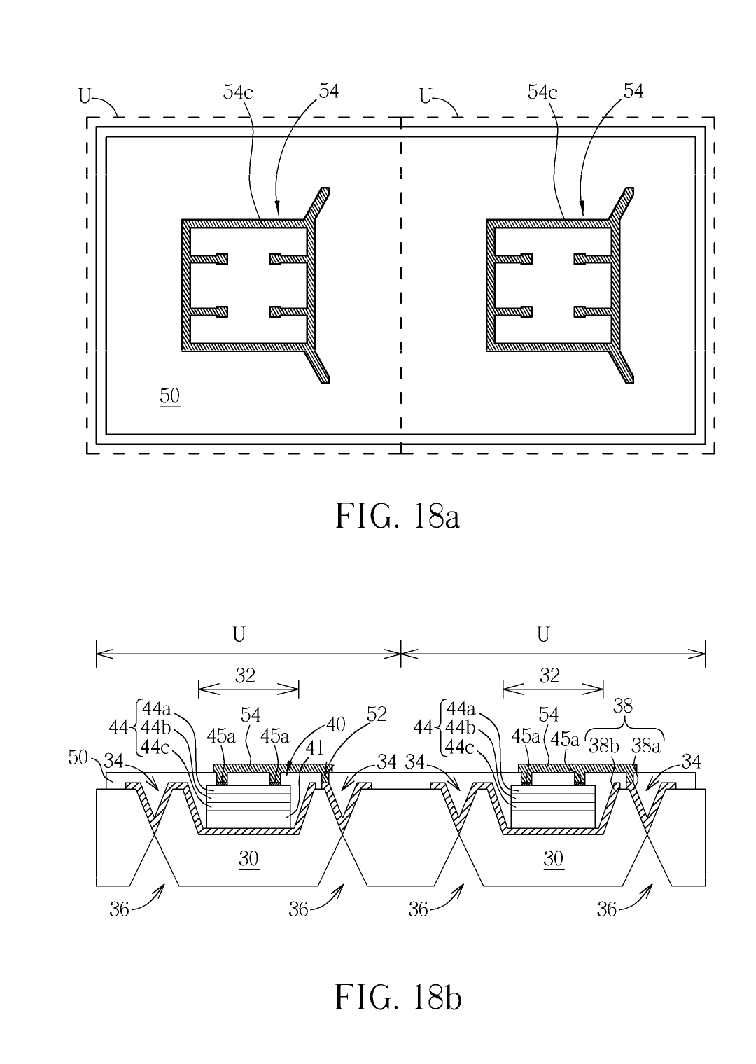

As shown in FIG. 18a and FIG. 18b, an upper patterned conductive layer 54 is formed on the planarization structure 50. The upper patterned conductive layer 54 is filled into the contact holes 52, so that each of the first lower patterned conductive layers 38a of the lower patterned conductive layer 38 is electrically connected to the first connecting pad 45a of each of the chips 40 via the upper patterned conductive layer 54. Hence, the first conductive type doped semiconductor layer 44a of the chips 40 is electrically connected to the first lower patterned conductive layers 38a via the upper patterned conductive layers 54. Preferably, the upper patterned conductive layer 54 includes a plurality of web electrode patterns 54c in the present embodiment, and each of web electrode patterns 54c is corresponding to each of the chip mounting areas 32. Each of the web electrode patterns 54c has a circular pattern; this design enables the electric potential at each point of the circular pattern to be the same. As a result, current is uniformly injected into the LED chips, and therefore the uniformity of light illumination is improved. The function of the upper patterned conductive layer 54 is the same as that of the lower patterned conductive layer 38, which is also served as the conductive wire. Thus, the material may be any single material or a complex material with good electrical conductivity, and the upper patterned conductive layer 54 may be formed by any kinds of thin film technologies depending on the selected material.

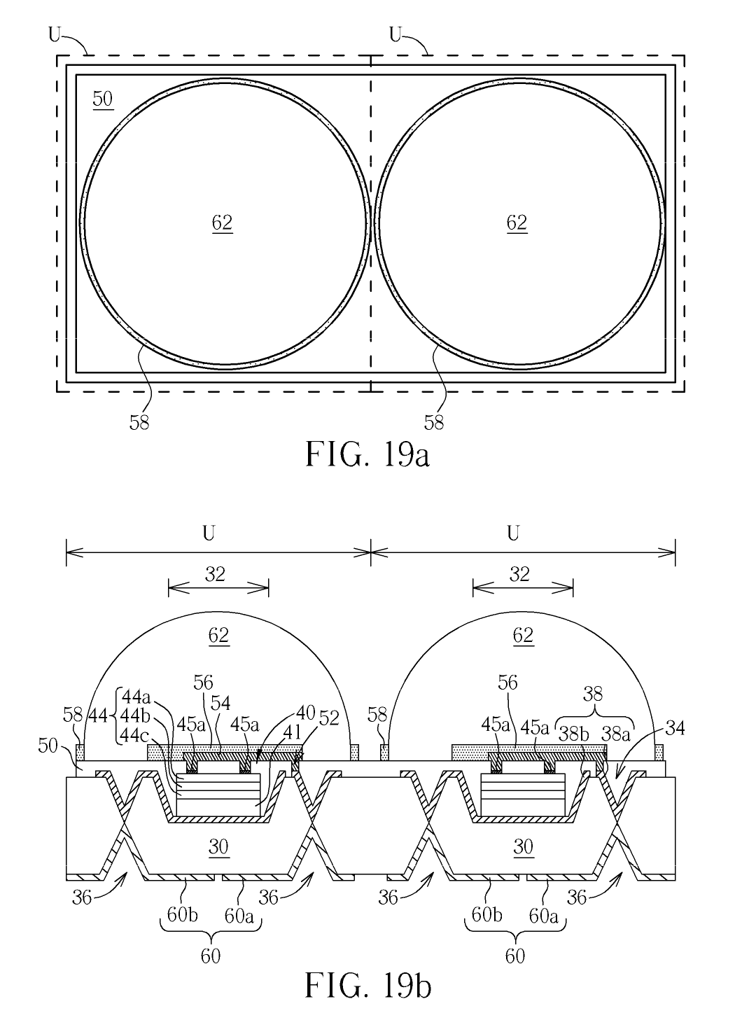

As shown in FIG. 19a and FIG. 19b, a chip package of the present embodiment is fabricated when a plurality of fluorescent patterns 56, a plurality of closed circular patterns 58 and a plurality of encapsulations 62 are formed on the upper surface of the package substrate 30, and a back patterned conductive layer 60 is formed on the lower surface of the package substrate 30 as the previous mentioned embodiment.

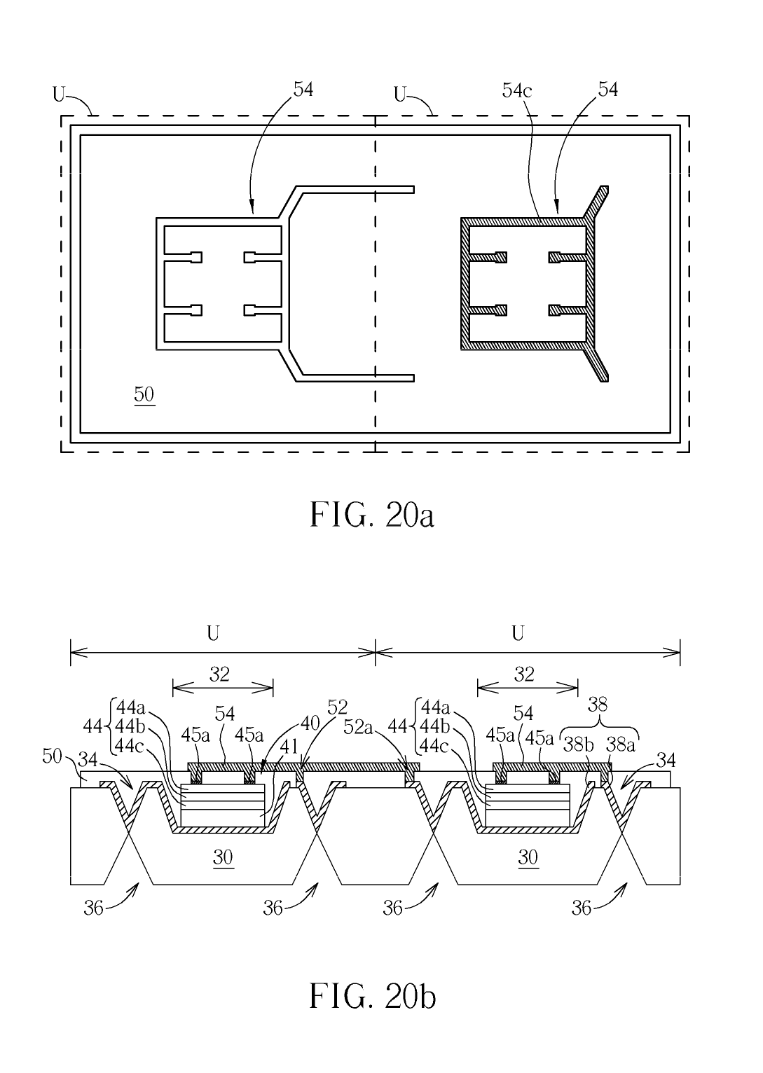

Please refer to FIG. 20. FIG. 20 is a schematic view illustrating electrical connection of a plurality of chips in series according to the present embodiment of the present invention. FIG. 20a is a top view, while FIG. 20b is a cross-sectional view. The serial electrical connection of the chips 40 are realized by redesigning the pattern of the planarization structure 50 and the upper patterned conductive layer 54, and an example of connecting two adjacent chips 40 in series is illustrated as follows. As shown in FIG. 20a and FIG. 20b, when patterning the planarization structure 50, at least a contact hole 52a in addition to the original contact holes 52 are formed in the planarization structure 50 of an unit A. The contact hole 52a exposes the second lower patterned conductive layer 38b. Next, the upper patterned conductive layer 54 of an adjacent unit B is filled into the contact holes 52 of itself (unit B). The upper patterned conductive layer 54 is also extended to the unit A and filled into the contact hole 52a, so that the two chips 40 of the units A, B are electrically connected to each other in series. In this embodiment, two LED chips are illustrated as an example of the present invention, but the number of the LED chips to be electrically connected in series is not limited and may be altered according to different requirements.

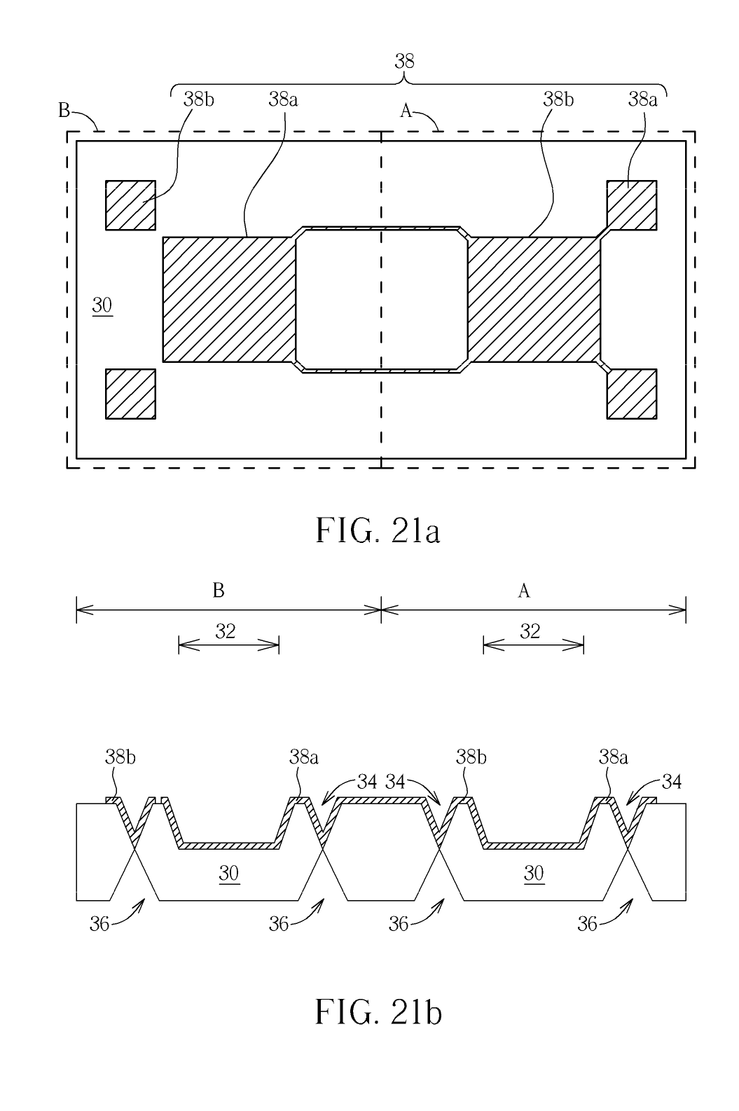

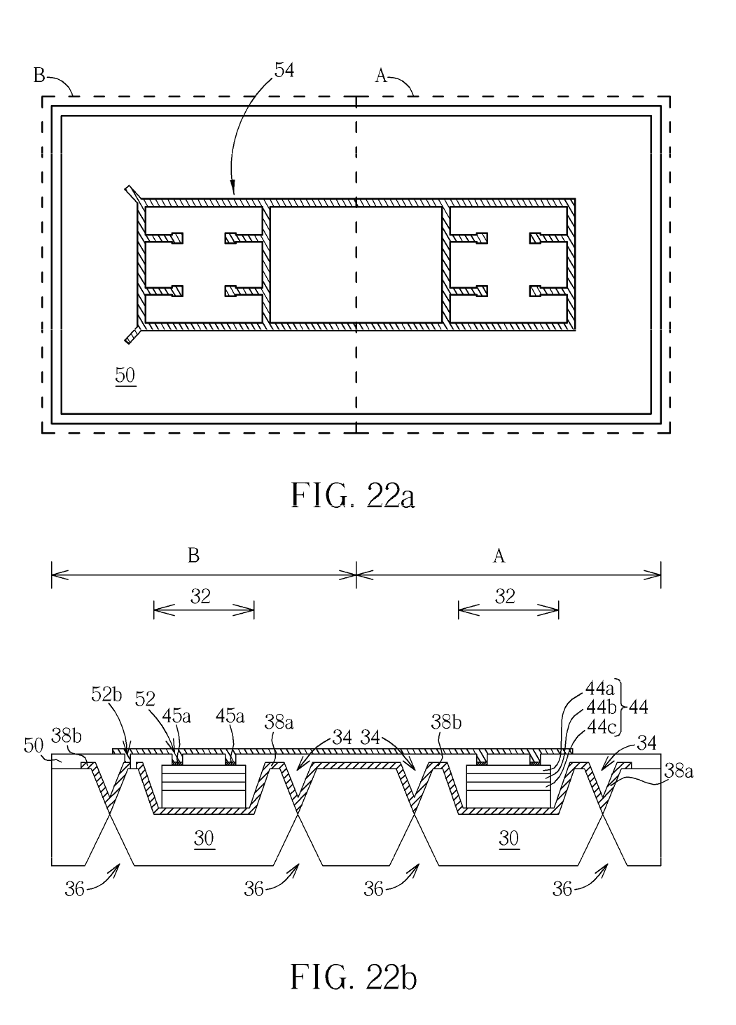

Please refer to FIG. 21 and FIG. 22. FIG. 21 and FIG. 22 are schematic views illustrating electrical connection of a plurality of chips in parallel according to the present embodiment of the present invention. FIG. 21a and FIG. 22a are top views, and FIG. 21b and FIG. 22b are cross-sectional views. The parallel electrical connection of the LED chips are realized by redesigning the lower patterned conductive layer 38, the pattern of the planarization structure 50 and the upper patterned conductive layer 54, and an example of connecting two adjacent chips 40 in parallel is illustrated as follows. First, as shown in FIG. 21a and FIG. 21b, when patterning the lower patterned conductive layer 38, the first lower patterned conductive layer 38a of a unit A, the second lower patterned conductive layer 38b of the unit A, and also the first lower patterned conductive layer 38a of an adjacent unit B are electrically connected. Next, as shown is FIG. 22a and FIG. 22b, after mounting the chips 40 into the chip mounting areas 32 respectively, the planarization structure 50 is formed on the package substrate 30, the lower patterned conductive layer 38 and the LED chips. The planarization structure 50 has a plurality of contact holes 52, which expose the first connecting pad 45a of the chips 40 of the units A, B, and at least a contact hole 52b which exposes the second lower patterned conductive layer 38b. Subsequently, the upper patterned conductive layer 54 is formed on the planarization structure 50. The upper patterned conductive layer 54 is filled into the contact holes 52 of the units A, B, and is also filled into the contact holes 52b of the unit B, so that the two LED chips of the units A, B are electrically connected to each other in parallel. In this embodiment, two LED chips are illustrated as an example of the present invention, but the number of the LED chips to be electrically connected in parallel is not limited and may be altered according to different requirements.

In sum, the chip package and the method of fabricating thereof in the present invention have the advantages as listed:
1. The package method in the present invention is a wafer level production method, and therefore is advantageous for its capability of batch production.
2. The chip package in the present invention utilizes semiconductor substrate having good heat dissipation ability as a package substrate.
3. The package substrate in the present invention has the design of through holes and back patterned conductive layer, which enables the connecting terminals of the chip to be conveyed from the upper surface to the lower surface of the package substrate, thus increasing the convenience to implement external connection.
4. The heat dissipation of the chip package in the present invention is carried out through the package substrate in the bottom of the chip mounting area, and the electricity transmission is delivered through the through holes located in the periphery of the chip mounting area and the back patterned conductive layer, hence, having the advantage of separating the transmission of heat and electricity.
5. The depth of the chip mounting areas of the chip package matches the thickness of the chips in the present invention, and the planarization structure is further filled into the space between the chips and the side walls of the chip mounting areas. Consequently, the package substrate has a planar surface after chip mounting, and this planar surface enables the layout of planar patterned conductive layer to be implemented.
6. The chip package in the present invention utilizes the planar patterned conductive layer as the connection layer, enabling the chips to electrically connect to each other in series and in parallel easily.
7. The chip package in the present invention has the design of closed circular pattern, enabling the maintenance of the surface tension of the encapsulation to be formed. Consequently, fabrication of lens may be performed easily.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of fabricating a chip package, comprising:
providing a package substrate, and forming a plurality of concave chip mounting areas on an upper surface of the package substrate;
providing a plurality of chips, each of the chips comprising:
an element substrate;
an element disposed on the element substrate; and
at least a first connecting pad and at least a second connecting pad disposed on an upper surface of the element;
mounting a lower surface of the element substrate of each of the chips within each of the chip mounting areas;
forming a planarization structure on the package substrate and the chips, and forming a plurality of contact holes in the planarization structure, wherein a portion of the first connecting pad and a portion of the second connecting pad of each of the chips are exposed by the contact holes; and
forming an upper patterned conductive layer on the planarization structure, wherein the upper patterned conductive layer is filled into the contact holes, and the upper patterned conductive layer is electrically connected to the first connecting pad and the second connecting pad of each of the chips.

2. The method of claim 1, wherein the package substrate comprises a semiconductor substrate.

3. The method of claim 1, further comprising forming a plurality of through holes in the package substrate before mounting the lower surface of the element substrate of each of the chips within each of the chip mounting areas.

4. The method of claim 3, wherein the step of forming the through holes in the package substrate comprises:
forming a plurality of upper through holes on the upper surface of the package substrate; and
forming a plurality of lower through holes corresponding to the upper through holes on a lower surface of the package substrate, so that the upper through holes and the corresponding lower through holes form the through holes.

5. The method of claim 4, wherein the upper through holes are formed by an anisotropic wet etching process.

6. The method of claim 5, wherein the chip mounting areas and the upper through holes are formed by the same anisotropic wet etching process.

7. The method of claim 4, wherein the lower through holes are formed by an anisotropic wet etching process.

8. The method of claim 4, further comprising forming a back patterned conductive layer on the lower surface of the package substrate and filling the back patterned conductive layer into the lower through holes.

9. The method of claim 8, wherein the planarization structure exposes the upper through holes, the upper patterned conductive layer is filled into the upper through holes, and is electrically connected to the back patterned conductive layer.

10. The method of claim 1, wherein the depth of the chip mounting areas and the thickness of the chip are substantially the same.

11. The method of claim 1, wherein the planarization structure comprises a photosensitive material layer and the planarization structure is patterned by an exposure-and-development process.

12. The method of claim 1, wherein the upper patterned conductive layer comprises a plurality of first upper patterned conductive layers and a plurality of second upper patterned conductive layers, each of the first upper patterned conductive layers is electrically connected to the first connecting pad of each of the chips and each of the second upper patterned conductive layers is electrically connected to the second connecting pad of each of the chips.

13. The method of claim 1, wherein the chips comprises a first chip and a second chip, the upper patterned conductive layer comprises a first upper patterned conductive layer and a second upper patterned conductive layer, the first upper patterned conductive layer is electrically connected to the first connecting pad of the first chip and the second connecting pad of the second chip, and the second upper patterned conductive layer is electrically connected to the second connecting pad of the first chip and the first connecting pad of the second chip, so that the first chip and the second chip are electrically connected in series.

14. The method of claim 1, wherein the chips comprises a first chip and a second chip, the upper patterned conductive layer comprises a first upper patterned conductive layer and a second upper patterned conductive layer, the first upper patterned conductive layer is electrically connected to the first connecting pad of the first chip and the first connecting pad of the second chip, and the second upper patterned conductive layer is electrically connected to the second connecting pad of the first chip and the second connecting pad of the second chip, so that the first chip and the second chip are electrically connected in parallel.

15. The method of claim 1, wherein each of the chips comprises a light emitting diode (LED) chip, and the element comprises a first conductive type doped semiconductor layer, a second conductive type doped semiconductor layer, and a light emitting layer disposed in between the first conductive type doped semiconductor layer and the second conductive type doped semiconductor layer.

16. A chip package, comprising:
a package substrate comprising at least a concave chip mounting area disposed on an upper surface of the package substrate;
at least a chip disposed within the chip mounting area, wherein the chip comprises:
an element substrate mounted on the package substrate;
an element disposed on the element substrate; and
at least a first connecting pad and at least a second connecting pad disposed on an upper surface of the element;
a planarization structure, having a planar surface, disposed on the package substrate and the chip, the planarization structure comprising a plurality of contact holes, wherein the first connecting pad and the second connecting pad are exposed by the contact holes; and
an upper patterned conductive layer disposed on the planarization structure, wherein the upper patterned conductive layer is filled into the contact holes, and the upper patterned conductive layer is electrically connected to the first connecting pad and the second connecting pad of the chip.

17. The chip package of claim 16, wherein the package substrate comprises a semiconductor substrate.

18. The chip package of claim 16, wherein the package substrate comprises a plurality of through holes disposed outside of the chip mounting area.

19. The chip package of claim 18, wherein each of the through holes comprises an upper through hole and a lower through hole corresponding to the upper through hole.

20. The chip package of claim 19, wherein the upper through hole and the lower through hole each comprises an outwardly-inclined side wall.

21. The chip package of claim 19, further comprising a back patterned conductive layer disposed on a lower surface of the package substrate, and the back patterned conductive layer is filled into the lower through holes.

22. The chip package of claim 21, wherein the planarization structure exposes the upper through holes, the lower patterned conductive layer is filled into the upper through holes, and electrically connected to the back patterned conductive layer.

23. The chip package of claim 16, wherein the depth of the chip mounting area and the thickness of the chip are substantially the same.

24. The chip package of claim 16, wherein the upper patterned conductive layer comprises a first upper patterned conductive layer and a second upper patterned conductive layer, the first upper patterned conductive layer is electrically connected to the first connecting pad of the chip, and the second upper patterned conductive layer is electrically connected to the second connecting pad of the chip.

25. The chip package of claim 16, wherein the at least one chip comprises a first chip and a second chip, the upper patterned conductive layer comprises a first upper patterned conductive layer and a second upper patterned conductive layer, the first upper patterned conductive layer is electrically connected to the first connecting pad of the first chip and the second connecting pad of the second chip, and the second upper patterned conductive layer is electrically connected to the second connecting pad of the first chip and the first connecting pad of the second chip, so that the first chip and the second chip are electrically connected in series.

26. The chip package of claim 16, wherein the at least one chip comprises a first chip and a second chip, the upper patterned conductive layer comprises a first upper patterned conductive layer and a second upper patterned conductive layer, the first upper patterned conductive layer is electrically connected to the first connecting pad of the first chip and the first connecting pad of the second chip, and the second upper patterned conductive layer is electrically connected to the second connecting pad of the first chip and the second connecting pad of the second chip, so that the first chip and the second chip are electrically connected in parallel.

27. The chip package of claim 16, wherein the chip comprises a light emitting diode (LED) chip, and the element comprises a first conductive type doped semiconductor layer, a second conductive type doped semiconductor layer, and a light emitting layer disposed in between the first conductive type doped semiconductor layer and the second conductive type doped semiconductor layer.

28. A method of fabricating a chip package, comprising:
providing a package substrate, and forming a plurality of concave chip mounting areas on an upper surface of the package substrate;
forming a lower patterned conductive layer on the upper surface of the package substrate, wherein the lower patterned conductive layer comprises a plurality of first lower patterned conductive layers and a plurality of second lower patterned conductive layers;
providing a plurality of chips, each of the chips comprising:
a conductive substrate;
an element disposed on the conductive substrate; and
a first connecting pad disposed on an upper surface of the element;
mounting a lower surface of the conductive substrate of each of the chips within each of the chip mounting areas, and electrically connecting the conductive substrate of each of the chips to each of the second lower patterned conductive layer;
forming a planarization structure on the package substrate and the chips, and forming a plurality of contact holes in the planarization structure, wherein a portion of the first connecting pad of each of the chips and the first lower patterned conductive layers are exposed by the contact holes; and
forming an upper patterned conductive layer on the planarization structure, wherein the upper patterned conductive layer is filled into the contact holes, so that each of the first lower patterned conductive layers of the lower patterned conductive layer is electrically connected to the first connecting pad of each of the chips via the upper patterned conductive layer.

29. The method of claim 28, wherein the package substrate comprises a semiconductor substrate.

30. The method of claim 28, further comprising forming a plurality of through holes in the package substrate before mounting the lower surface of the conductive substrate of each of the chips in each of the chip mounting areas.

31. The method of claim 30, wherein the step of forming the through holes in the package substrate comprises:
forming a plurality of upper through holes on the upper surface of the package substrate; and
forming a plurality of lower through holes corresponding to the upper through holes on a lower surface of the package substrate, so that the upper through holes and the corresponding lower through holes form the through holes.

32. The method of claim 31, wherein the upper through holes are formed by an anisotropic wet etching process.

33. The method of claim 32, wherein the chip mounting areas and the upper through holes are formed by the same anisotropic wet etching process.

34. The method of claim 31, wherein the lower through holes are formed by an anisotropic wet etching process.

35. The method of claim 31, further comprising forming a back patterned conductive layer on the lower surface of the package substrate, filling the back patterned conductive layer into the lower through holes, and filling the lower patterned conductive layer into the upper through holes so that the lower patterned conductive layer and the back patterned conductive layer are electrically connected.

36. The method of claim 28, wherein the depth of the chip mounting areas and the thickness of the chip are substantially the same.

37. The method of claim 28, wherein the planarization structure comprises a photosensitive material layer and the planarization structure is patterned by an exposure-and-development process.

38. The method of claim 28, wherein the upper patterned conductive layer comprises a plurality of web electrode patterns corresponding to the chip mounting areas respectively.

39. The method of claim 28, wherein the step of forming the upper patterned conductive layer further comprises electrically connecting the first connecting pad of the chip of one of the chip mounting areas to the second lower patterned conductive layer of another chip mounting area via the upper patterned conductive layer, so that the two chips are electrically connected in series.

40. The method of claim 28, wherein the step of forming the upper patterned conductive layer further comprises electrically connecting the first connecting pad of the chip of one of the chip mounting areas to the first lower patterned conductive layer of another chip mounting area via the upper patterned conductive layer, so that the two chips are electrically connected in parallel.

41. The method of claim 28, wherein the chip comprises a light emitting diode (LED) chip and the element comprises a first conductive type doped semiconductor layer, a second conductive type doped semiconductor layer, and a light emitting layer disposed in between the first conductive type doped semiconductor layer and the second conductive type doped semiconductor layer.

42. A chip package, comprising:
a package substrate comprising at least a concave chip mounting area disposed on an upper surface of the package substrate;
a lower patterned conductive layer disposed on the upper surface of the package substrate, wherein the lower patterned conductive layer comprises at least a first lower patterned conductive layer and at least a second lower patterned conductive layer;
at least a chip disposed in the chip mounting area, wherein the chip comprises:
a conductive substrate disposed on the second lower patterned conductive layer;
an element disposed on the conductive substrate; and
a first connecting pad disposed on an upper surface of the element;
a planarization structure, having a planar surface, disposed on the package substrate, the chip and the lower patterned conductive layer, the planarization structure comprising a plurality of contact holes, wherein the first connecting pad and the first lower patterned conductive layer are exposed by the contact holes; and
an upper patterned conductive layer disposed on the planarization structure, wherein the upper patterned conductive layer is filled into the contact holes, so that the first lower patterned conductive layer of the lower patterned conductive layer is electrically connected to the first connecting pad of the chip via the upper patterned conductive layer.

43. The chip package of claim 42, wherein the package substrate comprises a semiconductor substrate.

44. The chip package of claim 42, wherein the package substrate further comprises a plurality of through holes disposed outside of the chip mounting area, and the lower patterned conductive layer is electrically connected to a lower surface of the package substrate via the through holes.

45. The chip package of claim 44, wherein each of the through holes comprises an upper through hole and a lower through hole corresponding to the upper through hole.

46. The chip package of claim 45, wherein the upper through hole and the lower through hole each comprises an outwardly-inclined side wall.

47. The chip package of claim 45, wherein the lower surface of the package substrate comprises a back patterned conductive layer, the back patterned conductive layer is filled into the lower through holes, and the lower patterned conductive layer is filled into the upper through holes so as to electrically connect to the back patterned conductive layer.

48. The chip package of claim 42, wherein the depth of the chip mounting area and the thickness of the chip are substantially the same.

49. The chip package of claim 42, wherein the upper patterned conductive layer comprises a web electrode pattern corresponding to the chip mounting area.

50. The chip package of claim 42, further comprising another chip disposed in another chip mounting area, wherein the first connecting pad of the chip of the chip mounting area is electrically connected to the second lower patterned conductive layer of another chip mounting area via the upper patterned conductive layer, such that the two chips are electrically connected in series.

51. The chip package of claim 42, further comprising another chip disposed in another chip mounting area, wherein the first connecting pad of the chip of the chip mounting area is electrically connected to the first lower patterned conductive layer of another chip mounting area via the upper patterned conductive layer, such that the two chips are electrically connected in parallel.

52. The chip package of claim 42, wherein the chip comprises a light emitting diode (LED) chip and the element comprises a first conductive type doped semiconductor layer, a second conductive type doped semiconductor layer, and a light emitting layer disposed in between the first conductive type doped semiconductor layer and the second conductive type doped semiconductor layer.
